(19) United States
(12) Patent Application Publication
(10) Pub. No.: US 2026/0082486 A1
(43) Pub. Date: Mar. 19, 2026

(54) CIRCUIT

(71) Applicant: Chibitronics Inc., Wilmington, DE (US)

(72) Inventors: Jie Qi, New Port Richey, FL (US); Jonathan Samuelson, Lansing, MI (US)

(73) Assignee: Chibitronics Inc., Wilmington, DE (US)

(21) Appl. No.: 19/394,761

(22) Filed: Nov. 19, 2025

Related U.S. Application Data
(63) Continuation of application No. 19/199,866, filed on May 6, 2025.
(60) Provisional application No. 63/650,769, filed on May 22, 2024.
(60) Provisional application No. 63/721,283, filed on Nov. 15, 2024.

(51) Int. Cl. H05K 1/18; H01M 10/42; H01M 50/559

(52) U.S. Cl. CPC H05K 1/181; H01M 10/425; H01M 50/559; H05K 2201/10037; H05K 2201/1028

(57) ABSTRACT

A flexible circuit can include an electrically non-conductive substrate, a plurality of polymer particles deposited on the substrate, and an electrically conductive metallized foil. The polymer particles can be deposited onto the substrate according to a circuit trace pattern. The circuit trace pattern can define a path of at least one conductive circuit trace configured to couple electrically to a circuit element. The electrically conductive metallized foil can be configured to adhere to the polymer particles but not to the substrate to form the at least one conductive circuit trace.

### CROSS-REFERENCE TO RELATED APPLICATIONS

The present application is a continuation of U.S. patent application Ser. No. 19/199,866, filed on May 6, 2025, which claims the benefit of U.S. Provisional Patent Application No. 63/721,283, filed Nov. 15, 2024, and U.S. Provisional Patent Application No. 63/650,769, filed on May 22, 2024. The prior applications are incorporated by reference herein in their entireties.

### FIELD

The present application relates to a power source for a printed circuit.

### BACKGROUND

Typically, flexible printed circuits (which are also referred to herein as “flexible circuits”) can be fabricated using lithography by applying a photoresist layer to a copper-clad polyimide substrate, exposing the photoresist layer to UV light through a photomask having a desired circuit trace pattern, and etching the exposed copper layer of the copper-clad polyimide substrate to form circuit traces matching the desired circuit trace pattern. One drawback of the lithography process is that it involves high temperatures and corrosive acids, both of which limit the selection of flexible printed circuit substrates to plastics that can tolerate high temperatures and/or other extreme conditions.

Other methods of fabricating flexible printed circuits include screen printing processes, in which conductive inks are applied through stencils matching the desired circuit trace patterns onto flexible substrates to form circuit traces, and additive manufacturing processes, in which conductive inks are deposited onto flexible substates using specialized printers. However, one drawback of these processes is that the conductive inks may be less conductive and/or less durable than metal circuit traces formed using lithography.

Fabricating flexible printed circuits using these techniques typically requires complex, expensive equipment (for example, lithography process modules, specialized additive manufacturing printers) and skilled experts to operate this equipment. Furthermore, these techniques typically require users to generate flexible printed circuit designs (“circuit trace patterns”) using proprietary and/or hard-to-use design software. Finally, certain consumables (for example, acids for etching, conductive inks for screen printing or additive manufacturing) used in these techniques can be expensive, toxic, and/or hazardous.

Thus, current techniques for forming flexible circuits can require an expensive or otherwise prohibitive combination of complex equipment, skilled experts, and/or hazardous consumables. Accordingly, room for improvement exists.

Furthermore, flexible printed circuits can include power sources, such as one or more coin cell batteries. The power source can be secured to a substrate and/or a circuit trace of the flexible printed circuit in order to provide electrical power to one or more circuit elements also secured to the substrate and/or circuit trace. In some examples, the power source can become inadvertently dislodged from the flexible printed circuit and can thus pose a potential choking hazard or a potential electrical burn hazard if accidently swallowed by a child.

Additionally or alternatively, a need can exist to reduce or mitigate any leakage should the power source begin to leak.

Accordingly, room for improvement exists for safer, improved power sources.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one aspect, a flexible circuit kit can include at least one of a substrate and a toner ink layer printed onto the substrate or a circuit element. The flexible circuit kit can further include a carrier-backed foil that includes a metallized layer, a carrier layer coupled to the metallized layer, and a selectively adherable adhesive applied to the metallized layer. The selectively adherable adhesive can be selectively adherable to the toner ink layer.

In one aspect, a flexible circuit kit can include a carrier-backed foil and at least one of a substrate and a toner ink layer disposed at least partially over the substrate or a circuit element. The carrier-backed foil can include an adhesive layer, a metallized layer, a release layer directly coupled to the metallized layer, and a carrier layer. The selectively adherable adhesive layer of the carrier-backed foil can be selectively adherable to the toner ink layer.

In one aspect, a method of assembling a flexible circuit can include: placing a carrier-backed foil over a substrate and a toner ink layer printed onto the substrate, pressing the carrier-backed foil against the substrate and the toner ink layer, heating the carrier-backed foil, the substrate, and the toner ink layer, and removing a portion of the carrier-backed foil to form a circuit trace. The carrier-backed foil can include a selectively adherable adhesive that is selectively adherable to the toner ink layer.

In one aspect, a method can include providing a flexible circuit kit that includes at least one of a toner ink layer printed over a paper substrate or a circuit element, and a carrier-backed foil comprising a selectively adherable adhesive configured to selectively adhere to the toner ink layer. The method can further include, with a server computing system, over a computing network, receiving a request to download a flexible circuit trace pattern, and with the server computing system, in response to receiving the request over the computing network, providing a computer-readable file comprising the flexible circuit trace pattern.

In one aspect, a power source can include a battery with a first terminal and a second terminal, a first electrode coupled to the first terminal of the battery, a second electrode coupled to the second terminal of the battery, and a dielectric layer wrapped around the battery and partially wrapped around the first electrode and the second electrode.

In one aspect, a method of fabricating a power source can include coupling a first electrode to a battery, coupling a second electrode to the battery, and wrapping a dielectric layer around the battery and around portions of the first electrode and the second electrode.

In one aspect, a kit can include a power source, a first electrode, a second electrode, and a dielectric layer. The power source can include a battery with a first terminal and a second terminal. The first electrode can be coupled to the first terminal of the battery. The second electrode can be coupled to the second terminal of the battery. The dielectric layer can be wrapped around the battery and partially wrapped around the first electrode and the second electrode. The kit can further include at least one of a substrate and a circuit element, wherein the power source can be configured to be coupled to the substrate and the circuit element.

In one aspect, a power source can include a battery with a first terminal and a second terminal, a first electrode coupled to the first terminal of the battery, and a second electrode coupled to the second terminal of the battery.

In one aspect, a power source can include a battery with a first surface a second surface, a first terminal disposed on the first surface of the battery, and a second terminal disposed on the second surface of the battery. The first surface of the battery and the second surface of the battery can be separated by a third surface disposed between the first surface of the battery and the second surface of the battery, the third surface can be a side surface extending between the first and second surfaces and forming a perimeter surface of the battery, and the second surface can be opposite the first surface. The first terminal can have a first polarity, the second terminal can have a second polarity, and the second polarity can be different than the first polarity. The power source can further include a first electrode with a first end portion electrically coupled to the first terminal of the battery and a second end portion opposite the first end portion of the first electrode. The second end portion of the first electrode does not physically contact the first terminal of the battery. The power source can further include a second electrode with a first end portion electrically coupled to the second terminal of the battery and a second end portion opposite the first end portion of the second electrode. The second end portion of the second electrode does not physically contact the second terminal of the battery, and the second end portion of the first electrode and the second end portion of the second electrode are not in physical contact each other. The power source can further include a dielectric layer wrapped around at least a portion of the battery, the first end portion of the first electrode, and the first end portion of the second electrode. The dielectric layer does not cover the second end portion of the first electrode, and the dielectric layer does not cover the second end portion of the second electrode.

In one aspect, a method of fabricating a power source can include: coupling a proximal end portion of a first electrode to a first terminal of a battery. The battery can include a first surface and a second surface. The first surface of the battery and the second surface of the battery can be separated by a third surface disposed between the first surface of the battery and the second surface of the battery, the third surface can be a side surface, and the second surface can be opposite the first surface. The battery can further include the first terminal disposed on the first surface of the battery, wherein the first terminal can have a first polarity, and a second terminal disposed on the second surface of the battery, wherein the second terminal can have a second polarity, and wherein the second polarity can be different than the first polarity. The first electrode can include the proximal end portion and a distal end portion opposite the proximal end portion of the first electrode, wherein the distal end portion of the first electrode does not contact the first terminal of the battery. The method can further include coupling a proximal end portion of a second electrode to the second terminal of the battery, wherein the second electrode can include the proximal end portion and a distal end portion opposite the proximal end portion of the second electrode, wherein the distal end portion of the second electrode does not contact the second terminal of the battery, and wherein the distal end portion of the first electrode and the distal end portion of the second electrode do not contact each other. The method can further include wrapping a dielectric layer around at least a portion of the battery, the proximal end portion of the first electrode, and the proximal end portion of the second electrode. Wrapping the dielectric layer does not include wrapping the dielectric layer around the distal end portion of the first electrode, and wrapping the dielectric layer does not include wrapping the dielectric layer around the distal end portion of the second electrode.

In one aspect, a kit can include a power source and at least one of a substrate and a circuit element, wherein the power source can be configured to be coupled to the substrate or the circuit element. The power source can include a battery with a first surface, a second surface opposite the first surface, wherein the first surface of the battery and the second surface of the battery can be separated by a third surface disposed between the first surface of the battery and the second surface of the battery, a first terminal having a first polarity, wherein the first terminal can be located on the first surface of the battery, and a second terminal having a second polarity different than the first polarity of the first terminal, wherein the second terminal can be disposed on the second surface of the battery. The power source can further include a first electrode with a first end portion in contact with the first terminal of the battery and a second end portion not in physical contact the first terminal of the battery, a second electrode with a first end portion in contact with the second terminal of the battery and a second end portion not in physical contact the second terminal of the battery, wherein the second end portion of the first electrode and the second end portion of the second electrode do not physically contact each other, and a dielectric coating disposed around at least a portion of the battery including the first and second terminals of the battery, wherein the dielectric coating can cover the first end portion of the first electrode, wherein the dielectric coating can cover the first end portion of the second electrode, wherein the dielectric coating does not cover the second end portion of the first electrode, and wherein the dielectric coating does not cover the second end portion of the second electrode.

The foregoing and other objects, features, and advantages of the invention will become more apparent from the following Detailed Description, which proceeds with reference to the accompanying figures. As described herein, a variety of other features and advantages can be incorporated into the technologies as desired.

### BRIEF DESCRIPTION OF THE DRAWINGS

FIG. 1 illustrates a stage in a flexible circuit fabrication process according to an example, where a metal leaf is placed over a flexible substrate and a toner ink layer.

FIG. 2 illustrates another stage in the flexible circuit fabrication process of FIG. 1 where excess metal leaf is removed using a brush.

FIG. 3 illustrates another stage in the flexible circuit fabrication process of FIG. 1 where the excess metal leaf has been removed.

FIG. 4 is a top-down view of a flexible circuit that includes a first metal leaf and a second metal leaf, according to an example.

FIG. 5 is a view of a stage in a flexible circuit fabrication process according to an example, where a carrier-backed foil is placed over a flexible substrate and a toner ink layer.

FIG. 6 is a view of a stage in the flexible circuit fabrication process of FIG. 5, after the carrier-backed foil is placed over the flexible substrate and the toner ink layer.

FIG. 7 is a view of a stage in the flexible circuit fabrication process of FIG. 5 where the carrier-backed foil, the flexible substrate, the toner ink layer, and an optional sheet are heated using a laminator.

FIG. 8 is a view of a stage in the flexible circuit fabrication process of FIG. 5 where a release layer of the carrier-backed foil and a carrier layer of the carrier-backed foil are separated from a metallized layer of the carrier-backed foil.

FIG. 9 is a view of a stage in the flexible circuit fabrication process of FIG. 5 after the release layer and the carrier layer have been separated from the metallized layer to form a circuit trace of the flexible circuit.

FIG. 10 is a view of a stage in the flexible circuit fabrication process of FIG. 5 where a circuit element and a power source are coupled to the circuit trace of the flexible circuit.

FIG. 11 is a cross-sectional view of the stage of the flexible circuit fabrication process of FIG. 6, after the carrier-backed foil is placed over the flexible substrate and the toner ink layer.

FIG. 12 is a cross-sectional view of the stage of the flexible circuit fabrication process of FIG. 7, where the optional sheet has been placed over the carrier-backed foil, the flexible substrate, and the toner ink layer.

FIG. 13 is a cross-sectional view of the stage of the flexible circuit fabrication process of FIG. 8, where the release layer and the carrier layer of the carrier-backed foil are separated from the metallized layer of the carrier-backed foil.

FIG. 14 is a cross-sectional view of the stage of the flexible circuit fabrication process of FIG. 9, after the release layer and the carrier layer of the carrier-backed foil have been separated from the metallized layer of the carrier-backed foil.

FIG. 15 is a cross-section of a flexible circuit that includes a circuit trace coupled to an embossed region of a flexible substrate, according to an example.

FIG. 16 is a cross-section of a flexible circuit that includes a circuit trace coupled to a debossed region of a flexible substrate, according to an example.

FIG. 17 is a flow chart of the flexible circuit fabrication process of FIG. 1.

FIG. 18 is a flow chart of the flexible circuit fabrication process of FIG. 5.

FIG. 19 is a schematic view of a circuit sticker, according to an example.

FIG. 20 is a schematic view of a circuit sticker, according to an example.

FIG. 21A is a back view of a circuit sticker, according to an example.

FIG. 21B is a front view of the circuit sticker of FIG. 21A, wherein the circuit sticker is electrically connected to a circuit trace and a power source of a flexible circuit.

FIGS. 22A-22D are views of a power source and a circuit element, each with an attachment clip, according to an example.

FIGS. 23A-23C are views of a circuit element with an attachment magnet, according to an example.

FIG. 24A is a perspective view of a power source, according to an example.

FIG. 24B is a side view of the power source of FIG. 24A.

FIG. 24C is a top-down view of the power source of FIG. 24A.

FIG. 25A is a bottom-up view of a battery of a power source, according to an example.

FIG. 25B is a side view of the battery of FIG. 25A.

FIG. 25C is a top-down view of the battery of FIG. 25A.

FIG. 26A is a bottom-up view of a portion of the power source of FIG. 24A, with a first electrode, a second electrode, and a second dielectric layer removed, according to an example.

FIG. 26B is a side view of the portion of the power source of FIG. 26A.

FIG. 26C is a top-down view of the portion of the power source of FIG. 26A.

FIG. 27A is a perspective view of a portion of the power source of FIG. 24A.

FIG. 27B is a bottom-up view of the portion of the power source of FIG. 27A.

FIG. 28A is a perspective view of a first electrode of the portion of the power source of FIG. 27A.

FIG. 28B is a bottom-up view of the first electrode of FIG. 28A.

FIG. 28C is a side view of the first electrode of FIG. 28A.

FIG. 29A is a bottom-up view of a second electrode of the portion of the power source of FIG. 27A.

FIG. 29B is a side view of the second electrode of FIG. 29A.

FIG. 30 is a top-down view of a flexible circuit including the power source of FIG. 24A secured to circuit traces using conductive tape.

FIG. 31 is a top-down view of a flexible circuit including the power source of FIG. 24A secured to circuit traces using paper clips.

FIG. 32 is a top-down view of a flexible circuit including the power source of FIG. 24A secured to circuit traces using binder clips.

FIG. 33 is a top-down view of a flexible circuit, according to an example, wherein a power source of the flexible circuit is detached and flipped upside-down to show a plurality of foam pieces attached to a bottom surface of the power source.

FIG. 34 is a top-down view of the flexible circuit of FIG. 33, wherein the flexible circuit is in an open configuration.

FIG. 35 is a top-down version of the flexible circuit of FIG. 33, wherein the flexible circuit is in a closed configuration.

FIG. 36 is a top-down view of a flexible circuit, wherein a power source of the flexible circuit is detached and flipped upside-down to show a plurality of foam pieces attached to a bottom surface of the power source.

FIG. 37 is a top-down view of the flexible circuit of FIG. 33, wherein the flexible circuit is in an open configuration.

FIG. 38 is a top-down version of the flexible circuit of FIG. 33, wherein the flexible circuit is in a closed configuration.

### DETAILED DESCRIPTION

### General Considerations

For purposes of this description, certain aspects, advantages, and novel features of the embodiments of this disclosure are described herein. The disclosed methods, apparatus, and systems should not be construed as being limiting in any way. Instead, the present disclosure is directed toward all novel and nonobvious features and aspects of the various disclosed embodiments, alone and in various combinations and sub-combinations with one another. The methods, apparatus, and systems are not limited to any specific aspect or feature or combination thereof, nor do the disclosed embodiments require that any one or more specific advantages be present or problems be solved. The scope of this disclosure includes any features disclosed herein combined with any other features disclosed herein, unless physically impossible.

Although the operation of some of the disclosed examples are described in a particular, sequential order for convenient presentation, it should be understood that his manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods. Additionally, the description sometimes uses terms like “provide” or “achieve” to describe the disclosed methods. These terms are high level abstractions of the accrual operations that are performed. The actual operations that correspond to these terms may vary depending on the particular implementation and are readily discernible to one of ordinary skill in the art.

As used in the application and in the claims, the singular forms “a,” “an,” and “the” include the plural forms unless the context clearly dictates otherwise. Additionally, the term “includes” means “comprises.” Further, the terms “coupled” and “associated” generally mean electrically, electromagnetically, and/or physically (e.g., mechanically or chemically) coupled or linked and does not exclude the presence of intermediate elements between the coupled or associated items absent specific contrary language.

In the description, certain terms may be used such as “forward,” “front,” “rear,” “up,” “down,” “upper,” “lower,” “horizontal,” “vertical,” “left,” “right,” “longitudinal,” “lateral,” and the like. These terms are used, where applicable, to provide some clarity of description when dealing with relative relationships. However, these terms are not intended to imply absolute relationships, positions, and/or orientations. For example, with respect to an object, an “upper” surface can become a “lower” surface by turning the object over. Nevertheless, it is still the same object.

As used herein, “e.g.” means “for example,” and “i.e.” means “that is.”

### EXAMPLE OVERVIEW

Typically, flexible printed circuits can be fabricated using lithography by applying a photoresist layer to a copper-clad polyimide substrate, exposing the photoresist layer to UV light through a photomask having a desired circuit trace pattern, and etching the exposed copper layer of the copper-clad polyimide substrate to form circuit traces matching the desired circuit trace pattern. One drawback of the lithography process is that it involves high temperatures and corrosive acids, both of which limit the selection of flexible printed circuits substrates to plastics that can tolerate high temperatures and/or other extreme conditions.

Other methods of fabricating flexible printed circuits include screen printing processes, in which conductive inks are applied through stencils matching the desired circuit trace patterns onto flexible substrates to form circuit traces, and additive manufacturing processes, in which conductive inks are deposited onto flexible substates using specialized printers. However, one drawback of these processes is that the conductive inks may be less conductive and/or less durable than metal circuit traces formed using lithography.

Fabricating flexible printed circuits using these techniques typically requires complex, expensive equipment (for example, lithography process modules, specialized additive manufacturing printers) and skilled experts to operate this equipment. Furthermore, these techniques typically require users to generate flexible printed circuit designs (“circuit trace patterns”) using proprietary and/or hard-to-use design software. Finally, certain consumables (for example, acids for etching, conductive inks for screen printing or additive manufacturing) used in these techniques can be expensive, toxic, and/or hazardous.

Thus, current techniques for forming flexible circuits can require an expensive or otherwise prohibitive combination of complex equipment, skilled experts, and/or hazardous consumables. Accordingly, room for improvement exists.

In one aspect, the present disclosure provides kits for assembling flexible circuits, for example, “paper circuits” that include at least one of a metal leaf or a carrier-backed foil (which is also referred to herein as a “foil”) transferred onto a paper substrate. As used herein, the term “paper circuit” refers to flexible circuits with a paper substrate. However, the term “flexible circuit” should be understood to additionally encompass flexible circuits with non-paper substrates (for example, cloth substrates, plastic substrates, rubber substrates, etc.). Furthermore, it should be understood that the teachings disclosed herein can be applied to non-flexible (i.e., rigid) substrates, such as rigid plastic (e.g., polyimide), wood, stone, metal, etc. In one aspect, a flexible circuit kit can include a carrier-backed foil and at least one of a flexible substrate or a circuit element.

In some examples where the flexible circuit kit includes the flexible substrate, the flexible substrate can include a paper layer. In some of these examples, the flexible circuit kit can further include a toner ink layer disposed over (for example, printed on) at least a portion of the paper layer of the substrate. In some examples where the flexible circuit kit includes the carrier-backed foil, the carrier-backed foil can include an adhesive layer, a metallized layer, a release layer, and a carrier layer. The adhesive layer can be an adhesion coating that is selectively adherable to the toner ink layer but not the paper substrate. In some of these examples, the carrier-backed foil does not include a lacquer or decorative layer disposed between the metallized layer and the release layer. In some examples where the flexible circuit kit includes the circuit element, the circuit element can be a circuit sticker. The circuit sticker can include a flexible polyimide substrate, a wiring element, and an anisotropic conductive tape film bonding the flexible substrate to the wiring element. In some examples where the flexible circuit kit includes the circuit element, the circuit element can include one of an attachment clip or an attachment magnet.

The flexible circuit kit be used to fabricate a flexible circuit that includes circuit traces formed by the metallized layer of the carrier-backed foil. These circuit traces can be relatively more conductive than circuit traces formed using conductive inks in screen printing and additive manufacturing. Additionally, in some examples where the flexible circuit kit includes the flexible substrate, or where the flexible substrate is supplied by a user of the kit, the flexible substrate can be relatively more flexible than the copper-clad polyimide substrates used in lithography processes. Finally, the components of the flexible circuit kits can be relatively inexpensive and nontoxic compared to the components and consumables used to fabricate conventional flexible printed circuits. Therefore, the flexible circuits described in the present disclosure possess notable advantages over typical flexible printed circuits.

In addition to the improved flexible circuits, the present disclosure provides techniques for fabricating or assembling flexible circuits from flexible circuit kits. In one aspect, a method of assembling a flexible circuit can include placing a carrier-backed foil over a flexible substrate and a toner ink layer, pressing the carrier-backed foil against the flexible substrate and the toner ink layer, heating the carrier-backed foil, the flexible substrate, and the toner ink layer, and removing a portion of the carrier-backed foil to form a circuit trace. In this way, the method does not require expensive, complex, or hazardous equipment or materials, and can be performed using simple, inexpensive equipment found in homes or classrooms. Furthermore, since the steps of this method are relatively simple compared to steps of conventional flexible printed circuit fabrication methods, the disclosed methods can be performed by students, children, and/or hobbyists. Therefore, the techniques described in the present disclosure provide notable improvements over typical flexible circuit fabrication processes.

Examples 1-2 describe techniques for fabricating flexible circuits. Example 3 describes flexible circuits with three-dimensional substrates (for example, substrates with embossed or debossed regions). Example 4 describes circuit stickers of flexible circuits. Example 5 describes power sources and circuit elements of flexible circuits, wherein the power sources and circuit elements include attachment clips for coupling to circuit traces of the flexible circuits. Example 6 describes power sources and circuit elements of flexible circuits, wherein the power sources and circuit elements include attachment magnets for coupling to circuit traces of the flexible circuits. Example 7 describes power sources of flexible circuits, where the power sources include integrated electrodes for coupling to circuit traces of the flexible circuits.

Since the examples provided herein are primarily described with reference to flexible circuits that include paper substrates, the terms “paper circuit,” “paper circuit fabrication process,” and “paper circuit kit” may be used herein to refer to the “flexible circuit,” “flexible circuit fabrication process,” and “flexible circuit kit,” respectively. However, the usage of such terms should not be taken to limit the scope of the present disclosure because each example disclosed herein also embraces the use or inclusion of non-paper substrates (for example, cloth, plastic, rubber, leather, etc.). Furthermore, the scope of the present disclosure is not limited to flexible substrates, and each example disclosed herein also embraces the use or inclusion of relatively rigid substrates (for example, rigid plastic (for example, rigid polyimide), wood, stone, metal, etc.).

### Example #1: Flexible Circuit Fabrication Method

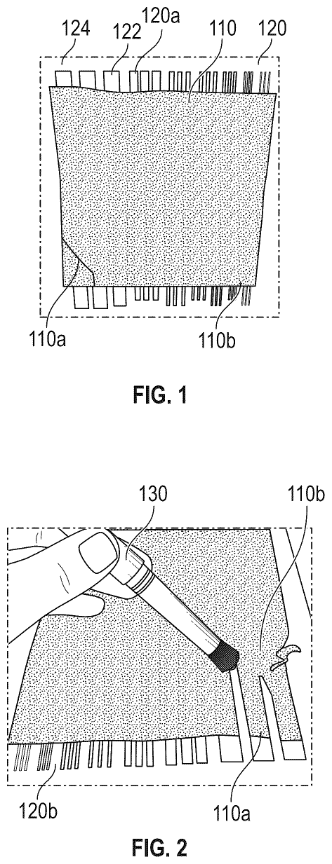

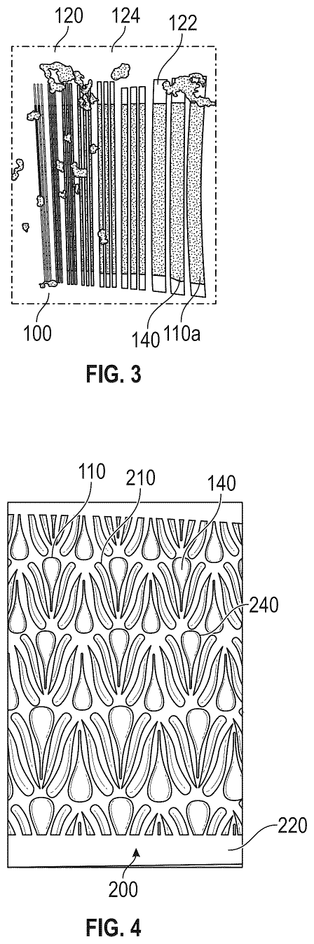

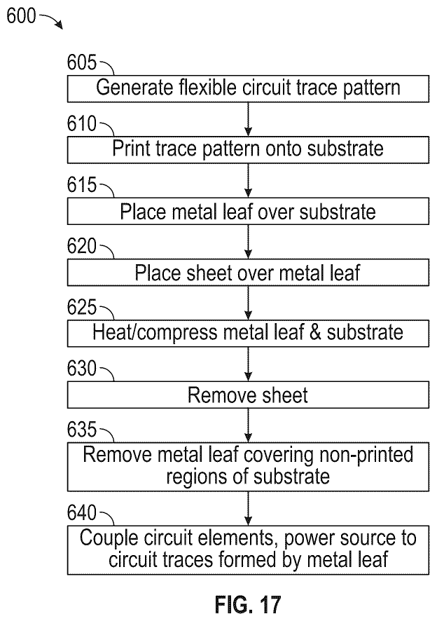

FIGS. 1-4 depict an example of a method of fabricating a flexible circuit 100 from a flexible circuit kit, according to an example. During the method, a user places a metal leaf 110 over a substrate 120 and a toner ink layer 122 (FIG. 1). Then, the user removes excess metal leaf 110 (FIG. 2), thereby resulting in the finished flexible circuit 100 (FIG. 3). In some aspects, the user can place a second metal leaf 210 over a substrate 220 (FIG. 4) to form a flexible circuit 200 that includes multiple pieces of metal leaf forming multiple circuit traces. The method of FIGS. 1-4 is further described in the flow chart 600 of FIG. 17. Although FIGS. 1-3 and 17 describe the method of fabricating a flexible circuit using one piece of metal leaf, other examples of this method can use multiple pieces of metal leaf, such as pieces of metal leaf having different conductive properties or appearances (for example, different colors).

FIG. 1 illustrates a stage in a flexible circuit fabrication process according to an example. In some examples, the flexible circuit kit can include the metal leaf 110, the substrate 120, and the toner ink layer 122. However, as described later herein, some examples of the flexible circuit kit do not include the substrate 120 and the toner ink layer 122 because the toner ink layer 122 can be applied to the substrate 120 during the flexible circuit fabrication process. As shown, the metal leaf 110 is placed over the substrate 120 and the toner ink layer 122. The metal leaf 110 can include of a sheet of a conductive material, such as any combination of aluminum, copper, gold, silver, etc. In some examples, a carrier-backed foil, such as carrier-backed foil 310 described later herein, can be used in this process in lieu of the metal leaf 110. In some examples, multiple types of carrier-backed foil can be used, and combinations of metal leaf and carrier-backed foil are embraced by the present disclosure.

As shown, the flexible substrate 120 (which is also referred to herein as a “substrate”) is a sheet of paper forming a paper layer 124. As further shown, the substrate 120 includes a first region 120a over which the toner ink layer 122 is disposed, formed, or printed. As discussed later herein, the first region 120a can correspond to a region on which circuit traces of the flexible circuit will be formed. The substrate 120 can further include a second region 120b. However, the toner ink layer 122 is not printed over the second region 120b. As discussed later herein, the second region 120b can correspond to a region on which circuit traces of the flexible circuit will not be formed.

The substrate 120 is primarily described throughout the Specification as being a “paper” substrate that includes the paper layer 124. However, it should be understood that this the full scope of the disclosed technology is not exclusively limited to paper substrates. In some examples, any one of the flexible circuit fabrication processes described herein can be performed using a cloth substrate (for example, a portion of any one of a piece of clothing, a flag, a bag, etc.), a cardboard substrate (for example, a portion of a box), a plastic substrate, or a substrate formed from any other suitable flexible material. Similarly, any one of the flexible circuits and any one of the flexible circuit kits disclosed herein can include non-paper substrates. Furthermore, the example circuit fabrication processes described herein are not exclusively limited to flexible substrates and can be performed using a relatively rigid substrate (for example, rigid plastic (for example, rigid polyimide), wood, stone, metal, etc.).

In some examples, the flexible substrate 120 can be a book or a portion thereof (for example, a cover or a page of the book), a container, a box, or a portion thereof (for example, a side, wall, or flap of the container or the box), a greeting card, a placard, a flag, a piece of clothing (for example, a hat, a dress, a shirt), a bag (for example, a paper or cloth bag). Thus, in some examples, the flexible circuit kit can include a book, a box, clothing, a bag, etc. In this way, flexible circuits can be formed on flexible portions of a variety of objects. Additionally, it should be understood that flexible circuits can be formed on non-flexible portions of objects.

Since the metal leaf 110 can be placed over the substrate 120, the metal leaf 110 can include a first portion 110a covering the first region 120a of the substrate 120 and a second portion 110b covering the second region 120b of the substrate 120. In some examples, the first portion 110a of the metal leaf 110 can be adhered to the toner ink layer 122 covering the first region 120a of the substrate 120. For example, the first portion 110a of the metal leaf 110 can be pressed against the toner ink layer 122 while the toner ink is still hot in order to adhere or fuse the first portion 110a of the metal leaf 110 to the first region 120a of the substrate 120 (in other words, to fuse or adhere the metal leaf 110 to the paper layer 124).

In some examples, the metal leaf 110 and the substrate 120, already combined with the toner layer 122, can be heated to facilitate the fusion or adhesion of the metal leaf 110 to the substrate 120. That is, the toner ink layer 122 can form a design (for example, a flexible circuit trace pattern) printed on the substrate 120. Later, the combination of the substrate 120 and toner ink layer 122 can be heated during, or prior to, the application of the metal leaf 110. In some examples, heating the metal leaf 110 and the substrate 120 can also heat the toner ink layer 122, which in a heated state can act as an adhesive. When the toner ink of the toner ink layer 122 cools, the toner ink can fuse or adhere the metal leaf 110 to the paper layer 124 of the substrate 120.

In some examples, the substrate 120 and/or the toner ink layer 122 is not provided as part of the flexible circuit kit. Instead, prior to placing the metal leaf 110 over the substrate 120 and the toner ink layer 122, the exemplary flexible circuit fabrication process can further include generating a flexible circuit trace pattern (which is also referred to herein as a “paper circuit trace pattern”). In some examples, the flexible circuit trace pattern can be a binary image consisting of a first color corresponding to the first region 120a (in other words, the region in which toner ink is to be applied) and a second color corresponding to the second region 120b (in other words, the region in which toner ink is not to be applied). However, flexible circuit trace patterns can be non-binary (for example, grayscale images or multicolor images) in other implementations. For example, multiple colors of toner can be used, where the metal leaf 110 can adhere to different colors of toner to varying degrees, including having colored toner to which the metal leaf does not adhere. The amount of toner can also be varied to control adherence properties, where, for example, lighter, including grayscale, patterns may to adhere to the metal leaf 110, or to a lesser degree than, for example, black toner.

In some examples, the flexible circuit trace pattern can be received from a server (which is also referred to herein as a “server computing system”). For example, the server can provide, over a computing network, the flexible circuit trace pattern to a client device or a printing device in response to receiving a download request over the computing network from the client device or the printing device. In some examples, the download request to the server can include a download code provided with the flexible circuit kit. For example, an entity (for example, a vendor) controlling the server can provide a user with a flexible circuit kit that includes the flexible circuit materials (for example, the metal leaf 110, circuit elements, power sources, etc.) and the download code. The user who receives the flexible circuit kit can use their client device or printing device to send the download code to the server to request a flexible circuit trace pattern. The server controlled by the entity can then provide the flexible circuit trace pattern in a computer-readable file (for example, a binary image file, a grayscale image file, a multicolor image file) to the user for printing. In this way, people who want to build flexible circuits can obtain different flexible circuit trace patterns without having to design the patterns themselves. In some examples, the download code and the flexible circuit kit can be provided separately.

In some examples, the flexible circuit trace pattern can be generated by flexible circuit design software. In such examples, the flexible circuit design software can be simpler and easier to use than conventional PCB design software since the flexible circuit design software can be a conventional document generation/image generation software (for example, MICROSOFT PAINT). Thus, the flexible circuit design software can allow those without specialized training or expertise—for example, children, students, and hobbyists—to use the software and design their own flexible circuit trace patterns. In some examples, the flexible circuit design software can be hosted on a server controlled by the same entity that provides users with flexible circuit kits, and access to the flexible circuit design software can be provided based on the receipt of an access code provided with the flexible circuit kit.

In some examples, the flexible circuit trace pattern can be printed using a laser printer by depositing and fusing the toner ink of the toner ink layer 122 onto the paper of the paper layer 124. In such examples, the toner ink can be transferred in a dry powder form from a drum of the laser printer onto the sheet of paper, and the toner ink can then be fused to the sheet of paper using one or more heated rollers of the laser printer. However, it should be understood that any suitable home- or industrial-scale printing method (for example, inkjet printing, gravure printing, 3D printing, solid ink printing, LED printing, hot stamping, cold stamping, digital stamping, etc.) can be used. In some examples, printing the substrate 120 shortly before the metal leaf 110 is placed over the substrate 120 can help ensure that the toner ink is sufficiently heated to fuse or adhere the metal leaf 110 to the substrate 120.

FIG. 2 illustrates another stage in the flexible circuit fabrication process of FIG. 1 where the second portion 110b of metal leaf 110 covering the second region 120b is removed using a brush 130. In some examples, since only the first portion 110a of the metal leaf 110 is adhered to the substrate 120 via the toner ink layer 122, the second portion 110b of the metal leaf 110 can be easily brushed off, leaving the first portion 110a of the metal leaf 110 intact.

FIG. 3 illustrates another stage in the flexible circuit fabrication process of FIG. 1 where the second portion 110b of the metal leaf 110 has been removed, leaving only the first portion 110a of the metal leaf 110 adhered to a portion of the toner ink layer 122 of the substrate 120. As shown, the first portion 110a of the metal leaf 110 defines one or more circuit traces 140 of the flexible circuit 100.

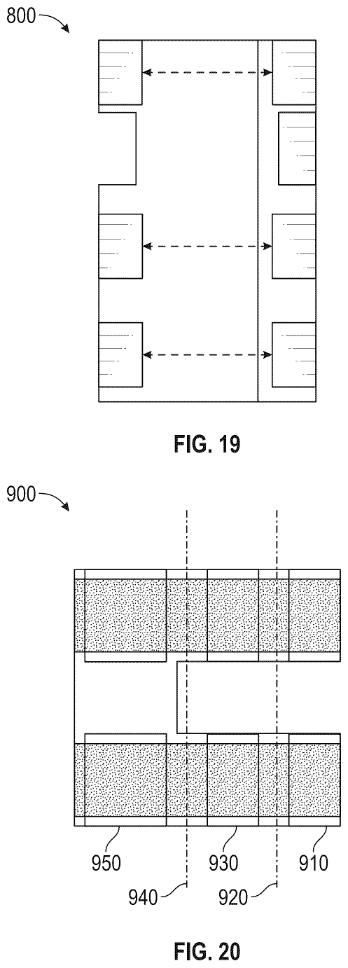

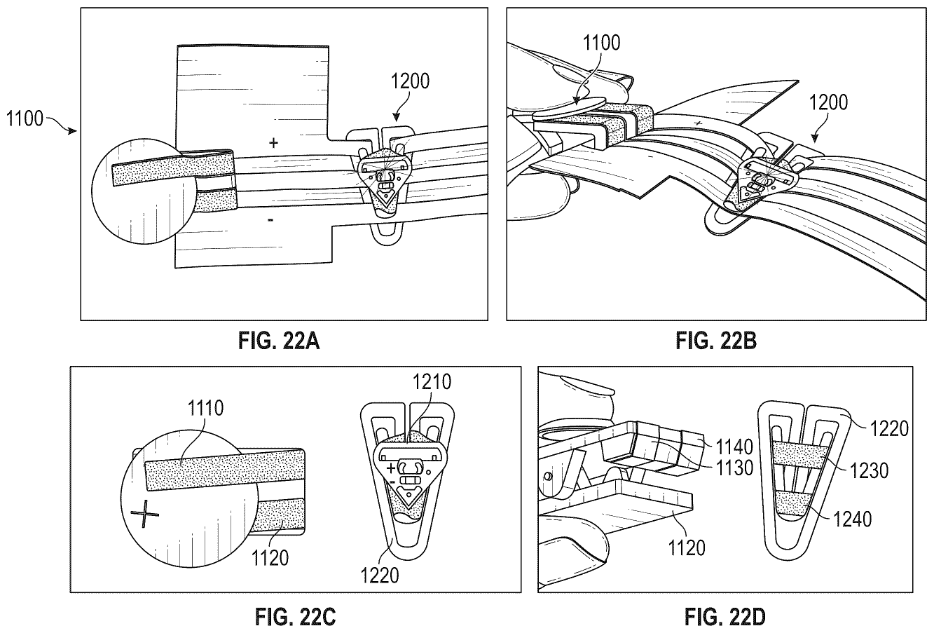

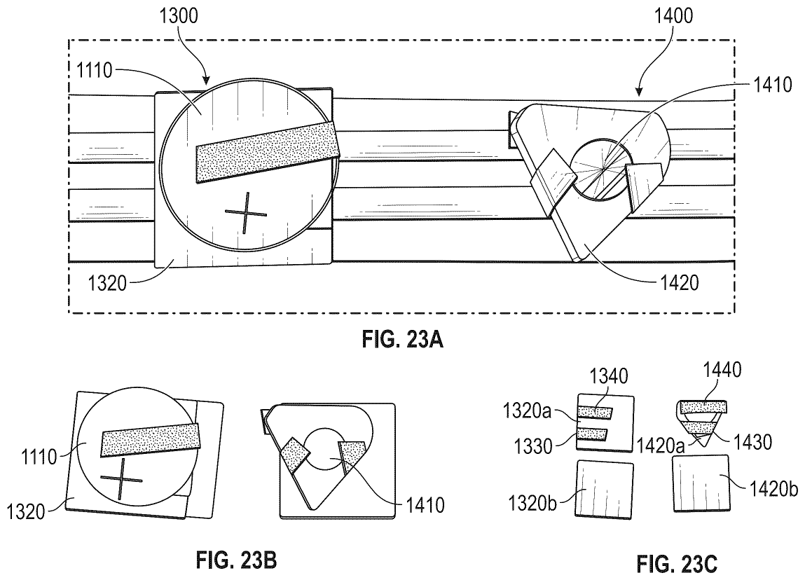

In some examples, the flexible circuit fabrication process can further include connecting to the circuit traces 140 one or more circuit elements that can be included in the flexible circuit kit. In some examples, the circuit elements can include any combination of sensors, transducers (for examples, speakers, motors), resistors, capacitors, inductors, transistors, switches, fuses, diodes (for example, LEDs), displays, power sources (for example, batteries, power cables), and programmable devices (for example, microcontrollers). In some examples, the circuit element can be a circuit sticker, examples of which are further described with reference to FIGS. 19-21. Circuit stickers are further described in U.S. Publication No. 2017/0135212, published May 11, 2017, which is incorporated by reference herein in its entirety. In some examples, the circuit element can include an attachment clip, examples of which are further described with reference to FIGS. 22A-22D. In some examples, the circuit element can include an attachment magnet, examples of which are further described with reference to FIGS. 23A-23C.

FIG. 4 is a top-down view of a flexible circuit 200, according to an example. One exemplary difference between the flexible circuit 100 shown in FIG. 3 and the presently illustrated flexible circuit 200 is that the flexible circuit 200 further includes a second metal leaf 210 that is disposed adjacent the metal leaf 110 (which is also referred to herein as a “first metal leaf”) on top of a substrate 220. The first metal leaf 110 and the second metal leaf 210 can both overlay and/or be adhered to the substrate 220 that can be—similar to the substrate 120—a sheet of paper. A toner ink layer can adhere the first metal leaf 110 and the second metal leaf 210 to the substrate 220. The flexible circuit 200 can be fabricated using a process similar to that illustrated in FIGS. 1-3, but instead utilizes multiple pieces of metal leaf rather than a single piece of metal leaf.

In some examples, the first metal leaf 110 can form a first circuit trace 140 of the flexible circuit 200 and the second metal leaf 210 can form a second circuit trace 240 of the flexible circuit 200. In some examples, the first circuit trace 140 can be electrically isolated from the second circuit trace 240. In this way, multiple electrical circuits can be formed on a single sheet of paper. In some examples, the first metal leaf 110 and the second metal leaf 210 can form a decorative design. Although FIG. 4 illustrates the two pieces of metal leaf, the first metal leaf 110 and the second metal leaf 210, it should be understood that the flexible circuit 200 can include any number of pieces of metal leaf (for example, three, four, five, six, etc.) arranged in any pattern, where again different pieces of metal leaf can have different conductive or visual properties, including being of varying thicknesses.

FIG. 17 is a flow chart 600 of the flexible circuit fabrication process illustrated in FIGS. 1-3, according to an example. Thus, the method illustrated in this flow chart 600 can be used to fabricate, from a flexible circuit kit, the flexible circuit 100 shown in FIG. 3 and/or the flexible circuit 200 shown in FIG. 4. However, this method can be used to fabricate other flexible circuits as well.

At block 605, a flexible circuit trace pattern can optionally be generated. The flexible circuit trace pattern can be a binary (two-color) image, wherein the first color corresponds to the region(s) on which the circuit traces will be formed, and wherein the second color corresponds to region(s) on which no circuit traces will be formed. Non-binary image representing circuit trace patterns can be generated in a similar manner. In some examples, the flexible circuit trace pattern can be generated by a user using a flexible circuit design software program. Since the flexible circuit design software only needs to generate a simple two-dimensional image, as opposed to a more complex conventional printed circuit board design, the flexible circuit design software can be simpler and more user-friendly than conventional circuit design software. Thus, the flexible circuit design software can allow children, students, hobbyists and others without specialized expertise or training to generate flexible circuit trace patterns.

In some examples, the optional step of block 605 can be omitted. For example, the flexible circuit trace pattern can be provided instead of being generated using the flexible circuit design software. A download request (for example, a download code that can be provided with the flexible circuit kit) can be sent to an external server. The server can then provide the flexible circuit trace pattern in response to receiving the download request.

At block 610, a substrate of the flexible circuit can optionally be fabricated by printing the flexible circuit trace pattern onto a sheet of paper using toner ink. Printing the flexible circuit trace pattern onto the paper can include depositing a layer of toner ink on the regions of the paper where circuit traces are to be formed. In some examples, the flexible circuit trace pattern can be printed using a home printing device, such as an inkjet printer, a solid ink printer, a LED printer, a 3D printer, etc. In some examples, the flexible circuit trace pattern can be printed using an industrial printing device, such as a gravure printer, a hot stamping machine, a cold stamping machine, a digital stamping machine, etc. However, it should be understood that the flexible circuit trace pattern can be printed using any suitable printing device using any suitable ink.

In some examples, the optional step of block 610 can be omitted. For example, the substrate can be pre-printed with the flexible circuit trace pattern and included in the flexible circuit kit, thereby negating the need for the flexible circuit trace pattern to be printed onto paper during the process.

At block 615, a metal leaf can be placed over the substrate and a toner ink layer formed by the toner ink deposited on top of the substrate. In some examples, the metal leaf can be placed over the entirety of the substrate. In some examples, multiple pieces of metal leaf can be placed over the substrate in order to form multiple circuit traces.

At block 620, a sheet can optionally be placed over the metal leaf, the substrate, and the toner ink layer. The sheet can be made of paper, tissue paper, plastic, etc. In some examples, the sheet can further hold the metal leaf in place relative to the substrate and/or the toner ink layer during a subsequent portion of the flexible circuit fabrication process. In some examples, the sheet can protect the metal leaf, the toner ink layer, and/or the substrate from damage.

At block 625, the metal leaf, the substrate, and the toner ink layer (and, in some examples, the optional sheet placed over the metal leaf and substrate) are heated and compressed. The metal leaf, the substrate, and the toner ink layer can be heated to a temperature at which the toner ink fuses or adheres the metal leaf to the paper of the substrate. In some examples, the metal leaf, the substrate, and the toner ink layer can be heated using a laminator. However, it should be understood that any suitable device (for example, hair dryers, ovens, irons, presses, etc.) can be used to apply heat and/or pressure to the metal leaf, the substrate, and the toner ink layer. The metal leaf, the substrate, and the toner ink layer can also be subjected to pressure in order to facilitate the fusing or adhesion of the metal leaf to the substrate. For example, the metal leaf can be compressed against the substrate by the laminator as it heats the metal leaf, the substrate, and the toner ink layer.

At block 630, the optional sheet placed over the metal leaf, the substrate, and the toner ink layer can be removed.

At block 635, metal leaf can be removed from the region(s) of the substrate are not covered by the layer of toner ink (in other words, the region(s) of the substrate where the circuit traces are not to be formed). In some examples, the metal leaf can be removed from these regions using a brush (for example, a hard-bristle brush). However, it should be understood that any suitable device can be used to remove the metal leaf. The remaining metal leaf can form a circuit trace of the flexible circuit.

At block 640, one or more circuit elements and/or power sources can be attached to the circuit trace(s) formed by the metal leaf. In some examples, the circuit elements can include any combination of sensors, transducers (for examples, speakers, motors), resistors, capacitors, inductors, transistors, switches, fuses, diodes (for example, LEDs), displays, power sources (for example, batteries, power cables), and programmable devices (for example, microcontrollers). In some examples, the circuit elements can be a circuit sticker. In some examples, the power source can be a battery. In some examples, the circuit elements and/or power source can be included in the flexible circuit kit. However, in some examples, the circuit elements and/or the power source can be provided separately from the flexible circuit kit.

In some examples, certain steps of this method (for example, the steps represented by blocks 615 through 635) can be repeated to apply a second metal leaf to the substrate and form a second circuit trace (for example, the second circuit trace 240 shown in FIG. 4).

### Example #2: Flexible Circuit Fabrication Method

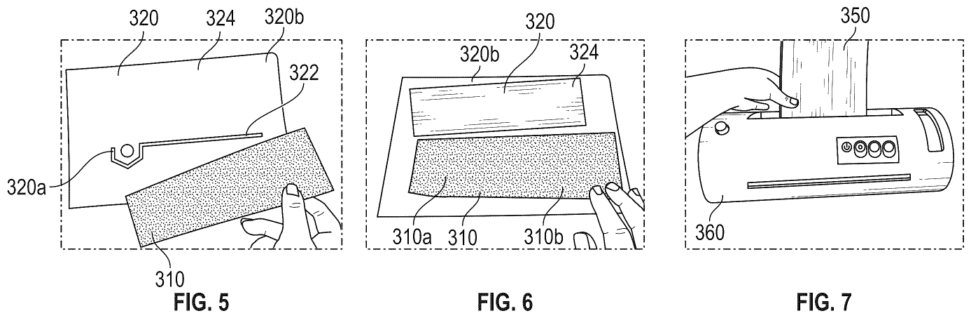

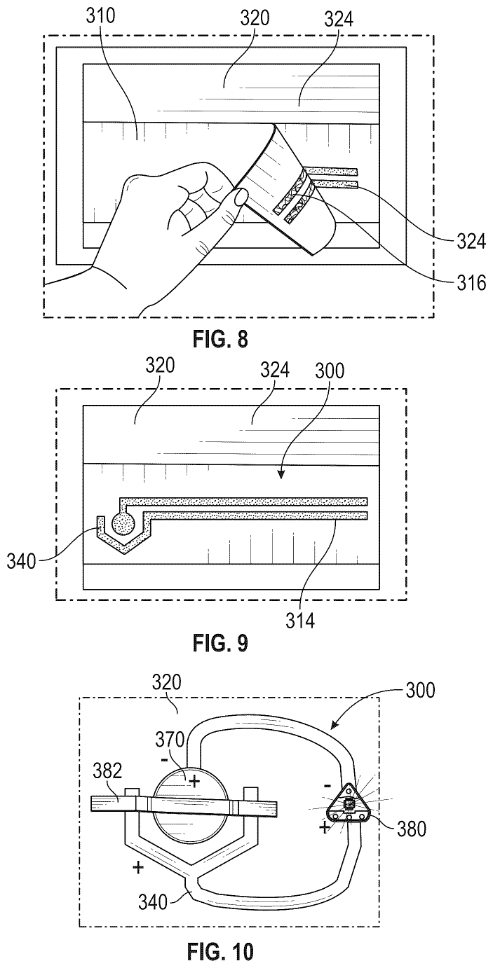

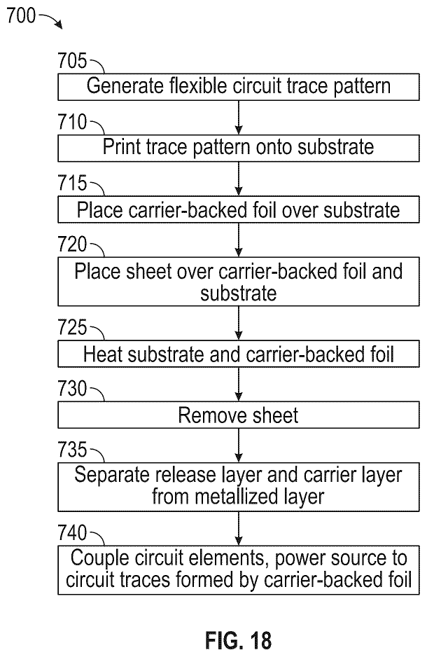

FIGS. 5-10 depict an example of a method of fabricating a flexible circuit 300 from a flexible circuit kit, according to an example. During the method, a user places a carrier-backed foil 310 (which is also referred to as a “stamping foil,” “digital foil,” and/or “foil”) over a substrate 320 and a toner ink layer 322 (FIGS. 5-6). Then, the user heats the carrier-backed foil 310, the substrate 320, the toner ink layer 322, and an optional sheet 350 using a laminator 360 (FIG. 7). Then, the user separates a carrier layer 318 of the carrier-backed foil 310, a release layer 316 of the carrier-backed foil 310, and the optional sheet 350 from a metallized layer 314 of the carrier-backed foil 310 (FIG. 8). Finally, the user optionally couples a circuit element 380 and a power source 370 to the metallized layer of the carrier-backed foil 310 (FIG. 10). FIG. 18 illustrates a flow chart 700 of this method.

FIG. 5 is a view of a stage in a flexible circuit fabrication process according to an example, where the carrier-backed foil 310 can be placed over the substrate 320 and the toner ink layer 322. The carrier-backed foil 310 can be included in the flexible circuit kit 300. The substrate 320 can include a paper layer 324 formed by a sheet of paper. The toner ink layer 322 can be disposed over (for example, printed on) the substrate 320. The substrate 320 can include a first region 320a corresponding to the region(s) at which circuit traces will be formed and a second region 320b at which circuit traces will not be formed. Thus, in some examples, the toner ink layer 322 can be printed onto only the first region 320a. In some examples, the substrate 320 and the toner ink layer 322 can be provided as part of the flexible circuit kit 300. However, in some examples, the toner ink layer 322 can be printed onto the substrate 320 as part of the flexible circuit fabrication process.

FIG. 6 is a view of a stage in the flexible circuit fabrication process of FIG. 5 after the carrier-backed foil 310 is placed onto the substrate 320 and the toner ink layer 322.

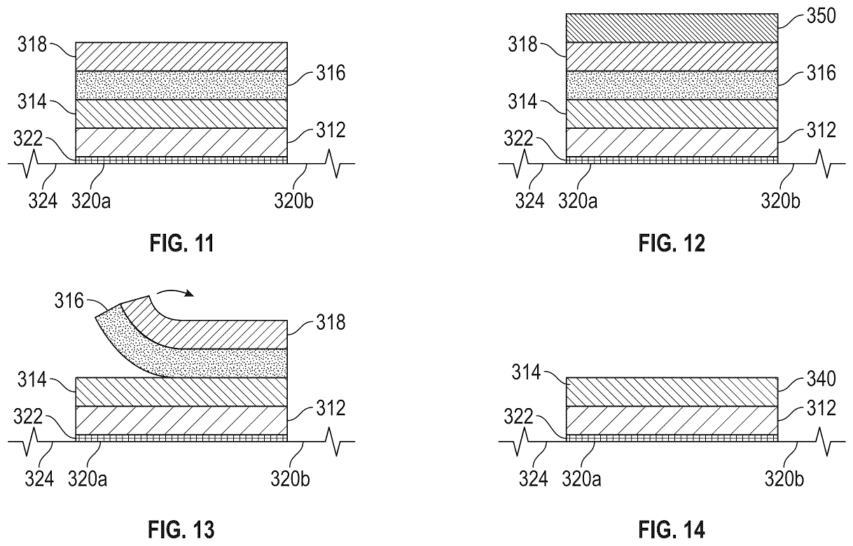

Now referring to FIG. 11, which is a cross-sectional view of the carrier-backed foil 310, the substrate 320, and the toner ink layer 322 during the stage illustrated in FIG. 6, the carrier-backed foil 310 can include an adhesive layer 312 (which is also referred to herein as an “adhesion coating” or an “adhesive”), a metallized layer 314 on top of the adhesive layer 312, a release layer 316 on top of the metallized layer 314, and a carrier layer 318 (which is also referred to herein as a “carrier film”) on top of the release layer 316. Thus, one difference between the metal leaf 110 and the carrier-backed foil 310 is that the carrier-backed foil 310 can additionally include any combination of the adhesive layer 312, the release layer 316, and/or the carrier layer 318. Like the metal leaf 110, the carrier-backed foil 310 can be used as a single piece of foil or multiple pieces of foil, such as foils as having different conductivities, widths, thicknesses, or visual appearances (for example, different colors).

The adhesive layer 312 can include a selectively adherable adhesive. As used herein, the term “selectively adherable” refers to an adhesive or bonding agent (where, for purposes of this disclosure, “adhesive” includes bonding agents that may be used with adhesives, and where the bonding agent facilitates selective adhesion) that is configured to adhere to specific materials or substrates while demonstrating minimal or no adhesion to others. This characteristic enables the adhesive to adhere selectively to certain surfaces while avoiding undesired adhesion to non-target materials.

In one example involving a laser printer, a selectively adherable adhesive can be selected to bond effectively to the toner ink deposited on the paper (such as bonding to polymer particles in the toner ink when the toner ink and paper are heated), while displaying little or no adhesion to the paper. This selective adhesion property ensures that the adhesive adheres only to the intended area, facilitating desired outcomes such as secure attachment or assembly while minimizing unwanted adhesion or residue. In the context of FIG. 3, elements of the carrier-backed foil 310 adhere to the toner ink layer 322 but not to the substrate 320. Thus, when the adhesive of the adhesive layer 312 is subjected to heat and/or pressure to activate it, the adhesive will selectively bond to the toner ink layer 322 but not bond to the paper layer 324 of the substrate 320. The term “digital printing foil” refers to a foil, such as a carrier-backed foil, which has a selectively adherable adhesive that can be used with substrates in digital printing techniques (that is, those involving the use of a computer).

The metallized layer 314 can include a sheet of a conductive material, such as any combination of aluminum, copper, gold, silver, etc. The release layer 316 can be a layer of flexible material (for example, a polymer) configured to facilitate the release of the metallized layer 314 of the carrier-backed foil 310 from the carrier layer 318. Thus, the release layer 316 can be detachably coupled to the metallized layer 314. In some examples, unlike some conventional tapes and foils, the carrier-backed foil 310 can lack a lacquer or decorative layer disposed between the metallized layer 314 and the release layer 316. Since the lacquer or decorative layer is less electrically conductive than the metallized layer 314, omitting the lacquer or decorative layer can ensure that circuit elements are better able to contact the more electrically conductive metallized layer 314. Thus, the release layer 316 can be directly and detachably coupled to the metallized layer 314. The carrier layer 318 can be a layer of polymer film (for example, a film that includes polyester or PET) that can be configured to provide structural support to the carrier-backed foil 310. One specific example of a carrier-backed foil with a selectively adherable adhesive layer is 1 mil ( 1/1000 inch) conductive aluminum foil (Item Code 320273ALU) from Quick Foils LLC of Montgomery, NY.

FIG. 7 is a view of a stage in the flexible circuit fabrication process of FIG. 5 where the carrier-backed foil 310, the substrate 320, and the toner ink layer 322 are heated and compressed. As shown, the carrier-backed foil 310, the substrate 320, and the toner ink layer 322 are heated by running them through the laminator 360. Heating the toner ink in the toner ink layer 322 can cause the toner ink to fuse or adhere the carrier-backed foil 310 to the paper layer 324 of the substrate 320. Heating the carrier-backed foil 310 can activate the adhesive of the adhesive layer 312. In some examples where the adhesive of the carrier-backed foil 310 is both heat- and pressure-activated, the laminator 360 can beneficially apply both heat and pressure to the carrier-backed foil 310 to activate its adhesive.

In some examples, the optional sheet 350 can be placed over the carrier-backed foil 310, the substrate 320, and the toner ink layer 322 prior to running them through the laminator 360. In some examples, the sheet 350 can further hold the carrier-backed foil 310 in place relative to the substrate 320 and/or the toner ink layer 322 during the lamination process. In some examples, the sheet 350 can protect the carrier-backed foil 310, the substrate 320, and/or the toner ink layer 322 from damage. The sheet 350 can be a sheet of printer paper, tissue paper, plastic, etc.

Now referring to FIG. 12, there is shown a cross-sectional view of the substrate 320, the carrier-backed foil 310 placed on top of the substrate 320, the toner ink layer 322 disposed between the carrier-backed foil 310 and the substrate 320, and the optional sheet 350 placed on top of the carrier-backed foil 310 during the stage illustrated in FIG. 7.

FIG. 8 is a view of a stage in the flexible circuit fabrication process of FIG. 5 where the release layer 316 of the carrier-backed foil 310 and the carrier layer 318 of the carrier-backed foil 310 are separated from the metallized layer 314 of the carrier-backed foil 310. As shown, this step can be accomplished by peeling back the release layer 316 and the carrier layer 318. The optional sheet 350 can also be peeled back with the release layer 316 and the carrier layer 318 or can be removed prior to peeling back the release layer 316 and the carrier layer 318.

Now referring to FIG. 13, there is shown a cross-sectional view of the release layer 316 and the carrier layer 318 being peeled back and separated from the metallized layer 314 of the carrier-backed foil 310 during the stage illustrated in FIG. 8.

FIG. 9 is a view of a stage in the flexible circuit fabrication process of FIG. 5 after the release layer 316, the carrier layer 318, and the sheet 350 have been separated from the metallized layer 314. As shown, peeling back the release layer 316, the carrier layer 318, and the sheet 350 removes a portion 310b of the carrier-backed foil 310 (specifically, the metallized layer 314) covering the second region 320b of the substrate 320. Since the carrier-backed foil 310 selectively adheres only to the exposed toner ink layer 322 printed onto the first region 320a of the substrate 320 (and not to the exposed paper layer 324 of the second region 320b), a remaining portion 310a of the carrier-backed foil 310 that includes the metallized layer 314 only covers the first region 320a of the substrate 320. The remaining portion 310a of the carrier-backed foil 310 defines one or more circuit traces 340 of the resulting flexible circuit 300.

Now referring to FIG. 14, there is shown a cross-sectional view of the circuit trace 340 formed by the remaining metallized layer 314 and the adhesive layer 312 of the carrier-backed foil 310 during the stage illustrated in FIG. 9.

FIG. 10 is a view of a stage in the flexible circuit fabrication process of FIG. 5 where one or more circuit elements 380 and one or more power sources 370 have been coupled to the circuit traces 340, thereby resulting in the finished flexible circuit 300. In some examples, the circuit elements 380 can include any combination of sensors, transducers (for examples, speakers, motors), resistors, capacitors, inductors, transistors, switches, fuses, diodes (for example, LEDs), displays, power sources (for example, batteries, power cables), and programmable devices (for example, microcontrollers). For example, as shown, the circuit element 380 is a circuit sticker adhered to the substrate 320 and to the circuit trace 340. As shown, the power source 370 is a coin cell battery coupled to the circuit trace 340 using conductive tape 382. However, the power source 370 can be coupled to the circuit trace 340 in any manner.

In some examples, the circuit elements 380 and/or the power sources 370 can be included in the flexible circuit kit. However, in some examples, the circuit elements 380, the power sources 370, and the flexible circuit kit can be provided separately.

FIG. 18 is a flow chart 700 of the flexible circuit fabrication process illustrated in FIGS. 5-10 and 11-14, according to an example. Some steps in the flow chart 700 can be similar to corresponding steps in the flow chart 600 of FIG. 17, which are referred to by similar reference numbers offset by 100. For example, the steps at blocks 705 and 710, at which a flexible circuit trace pattern is generated and printed onto the substrate 320, can be similar to the steps represented by blocks 605 and 610 in the flow chart 600 of FIG. 17.

At block 715, the carrier-backed foil 310 can be placed over the substrate 320 and the toner ink layer 322.

At block 720, the optional sheet 350 is placed over the carrier-backed foil 310, the substrate 320, and the toner ink layer 322.

At block 725, the carrier-backed foil 310, the substrate 320, the toner ink layer 322, and the optional sheet 350 are heated and compressed, for example, using the laminator 360.

At block 730, the optional sheet 350 is removed.

At block 735, the release layer 316 and the carrier layer 318 of the carrier-backed foil 310 are peeled back and separated from the metallized layer 314 of the carrier-backed foil 310 to reveal circuit traces 340 of the flexible circuit 300.

At block 740, one or more circuit elements 380 and/or power sources 370 can be coupled to the circuit traces 340 of the flexible circuit 300.

In some examples, the steps at blocks 715 through block 735 can be repeated to form a second circuit trace of the flexible circuit 300. Similar to the second circuit trace 240 shown in FIG. 4, the second circuit trace of the flexible circuit 300 can be electrically isolated from the circuit trace 340 (which is also referred to herein as a “first circuit trace”). In some examples, the first and second circuit traces can have different conductive or visual properties, including being of varying thicknesses.

### Example #3: Flexible Circuits with Three-Dimensional Substrates

In some examples, any one of the disclosed flexible circuit fabrication processes can be combined with embossing and/or debossing techniques to fabricate flexible circuits with three-dimensional substrates. In some examples, as described further below, the three-dimensional substrates can beneficially facilitate the flexible circuit fabrication process. Additionally, three-dimensional substrates can make the flexible circuit aesthetically appealing.

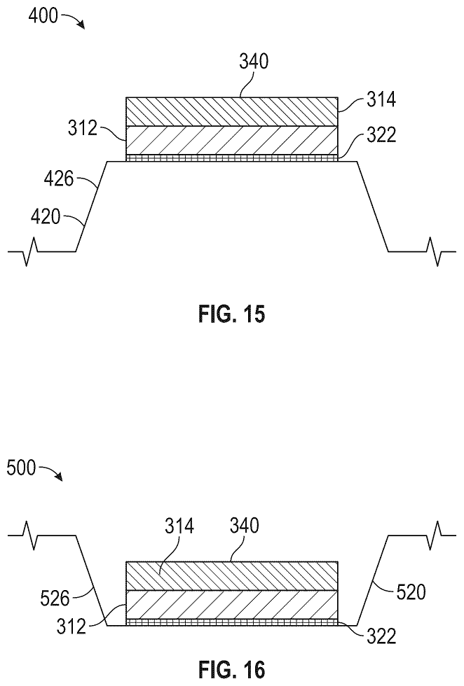

FIG. 15 is a cross-section of an embossed flexible circuit 400 that includes the circuit trace 340 formed on an embossed region 426 (which is also referred to herein as a “raised region”) of a substrate 420, according to an example. Although the illustrated circuit trace 340 is formed from the carrier-backed foil 310 using the method described with reference to FIGS. 5-10, 11-14, and 18, other examples of embossed flexible circuits can additionally or alternatively include circuit traces formed from the metal leaf 110 using the method described with reference to FIGS. 1-4 and 17. The embossed region 426 can be created using a hot stamping technique, in which the carrier-backed foil 310 is transferred onto the substrate 420 using a heated die with raised or lowered regions corresponding to the embossed region 426. In some examples, the embossed region 426 can be formed prior to or after adhering the carrier-backed foil 310. In some examples, forming the circuit trace 340 on the embossed region 426 of the substrate 420 can beneficially improve mechanical contact and/or electrical contact between the circuit trace 340 and a power source (for example, power source 370) or circuit element (for example, circuit element 380) coupled to the circuit trace 340. In some examples, forming the circuit trace 340 on the embossed region 426 of the substrate 420 can help users more easily find the circuit trace 340 and/or attach components to the circuit trace 340.

FIG. 16 is a cross-section of a flexible circuit 500 that includes the circuit trace 340 formed on a debossed region 526 (which is also referred to herein as a “depressed region”) of a substrate 520, according to an example. Similar to the embossed region 426, the debossed region 526 can be formed using the hot stamping technique. In some examples, forming the circuit trace 340 on the debossed region 526 of the substrate 520 can beneficially create a groove or footprint that can be used to better align the circuit element 380 or the power source 370 with the circuit trace 340 disposed within the debossed region 526.

### Example #4: Circuit Stickers for Flexible Circuits and Flexible Circuit Kits

Aspects of the present disclosure include electronic sticker technology to enable the assembly of circuits at ambient temperature without the use of any special tools. Through the use of isotropically or (more typically) anisotropically conductive adhesives, functional circuit elements are combined with wire elements using nothing more than a peel-and-stick motion.

FIG. 19 illustrates the basic anatomy of a “clamp & test” circuit sticker 800. The circuit sticker 800 can include a flexible substrate and a first wiring element. The first wiring element can be bonded to the flexible substrate with an anisotropic conductive tape film. The anisotropic conductive tape film can conduct current through a thickness of the anisotropic conductive tape film but not through a width or length of the anisotropic conductive tape film. The flexible substrate can be polyimide with coverlay, which accounts for enhanced flexibility and robustness to repeated flexing. The first wiring element can be metal wire, metal foil, metal tape, metal fabric, metal thread, metal foils, metal inks, suspensions of conductive nanoparticles, carbon-based inks, or conductive film.

FIG. 20 illustrates an example of a multiple-stick variant of a flexible circuit 900. Anisotropic tape can be only applied in the hatched regions, over exposed electrode lines. Each tape island can have its own protective wax backing. In the case above, there are only two electrodes but the sticker can have more. In this scenario, the user would first peel-and-stick using the electrodes at 910. When the sticker is desired to be re-used, the sticker is cut along line 920, and electrodes at 930 are exposed and stuck into a new circuit. Finally, the sticker can be cut along line 940 and used one last time by exposing the electrodes at 950.

It is important to note that the multiple re-use technique is simply a method of decorating an electrode, and is thus compatible with the “clamp & test” variant. Specifically, the electrodes on the clamp & test variant can be extended to be longer and have adhesive applied selectively to create the similar form presented here.

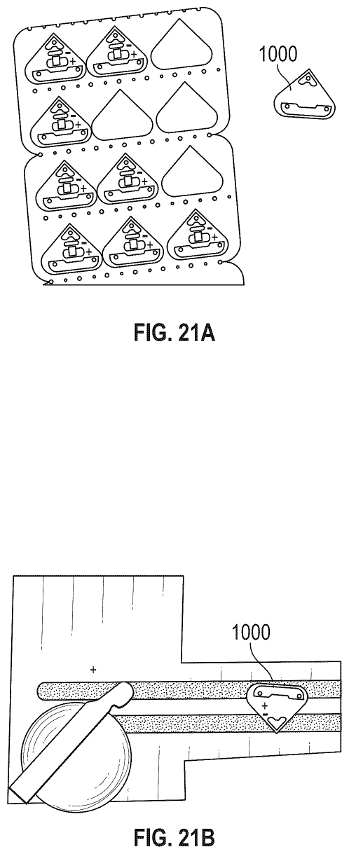

FIG. 21A-21B are back and front views of a circuit sticker 1000, according to an example. As shown in FIG. 21A, the circuit stickers 1000 can be packaged as a sheet of circuit stickers.

In the circuit stickers 800, 900, and 1000, additional polyimide stiffeners (strips of PI film ˜0.3 mm in thickness) may be laminated onto the flexible substrate to improve the robustness of the clamping or re-use points. This is particularly relevant for the “clamp & test” variant 800, because without the stiffener, free-hanging alligator clips can easily tear into and damage the thin, flexible circuit material.

Additional description of the circuit stickers 800, 900, and 1000 can be found in U.S. Pat. No. 9,999,128, which was previously incorporated by reference above in its entirety.

### Example #5: Circuit Elements with Attachment Clips for Flexible Circuits and Flexible Circuit Kits

FIGS. 22A-22D illustrate a power source 1100 and a circuit element 1200, according to an example. As shown in FIGS. 22C-22D, the power source 1100 can include a coin cell battery 1110 coupled to an attachment clip 1120. However, any power source (for example, a power cable, any type of battery, a solar panel, a generator) can be used with the attachment clip 1120. The power source 1100 can include a first lead 1130 spaced apart from a second lead 1140 on the attachment clip 1120, wherein the first and second leads 1130 and 1140 are each in electrical contact with different terminals of the coin cell battery 1110. As shown in FIGS. 22A-22B, clipping the attachment clip 1120 to circuit traces of a flexible circuit can complete an electrical circuit, thereby allowing the coin cell battery 1110 to power the flexible circuit. In this way, the power source 1100 can be easily coupled or decoupled from a flexible circuit in a repeatable, non-destructive way that does not damage the circuit traces of the flexible circuit and in a way that does not require tools.

As shown in FIGS. 22C-22D, the circuit element 1200 can include a LED 1210 coupled to an attachment clip 1220 with a first lead 1230 and a second lead 1240. Although the circuit element 1200 is pictured with the LED 1210, any type of circuit element (a sensor, actuator, display, etc.) can be used with the attachment clip 1220. As shown in FIGS. 22A-22B, coupling the first lead 1230 and a second lead 1240 of the circuit element 1200 to circuit traces of a flexible circuit using the attachment clip 1220 can complete an electrical circuit, thereby allowing the circuit element 1200 to be powered by a power source, such as power source 1100.

### Example #6: Circuit Elements with Attachment Magnets for Flexible Circuits and Flexible Circuit Kits

FIGS. 23A-23C illustrate a power source 1300 and a circuit element 1400, according to an example. As shown in FIGS. 23B-23C, the power source 1300 can include the coin cell battery 1110 coupled to an attachment magnet 1320. As shown in FIG. 23C, the attachment magnet 1320 can include a first half 1320a and a second half 1320b. The power source 1300 can include a first lead 1330 spaced apart from a second lead 1340, wherein each lead 1330 and 1340 is disposed on the first half 1320a of the attachment magnet 1320 and each lead 1330 and 1340 is in electrical contact with the coin cell battery 1110. As shown in FIG. 23A, the circuit traces and the substrate of a flexible circuit can be placed between the first half 1320a and the second half 1320b of the attachment magnet 1320 to detachably couple the power source 1300 to the circuit traces in a repeatable, non-destructive manner that does not require specialized tools.

Similarly, as shown in FIGS. 23B-23C, the circuit element 1400 includes the LED 1410 coupled to an attachment magnet 1420. The attachment magnet 1420 includes a first half 1420a and a second half 1420b. As shown, the first half 1420a includes a first lead 1430 and a second lead 1440 coupled to the terminals of the LED 1410. The circuit element 1400 can be coupled to a circuit trace in the same manner as the power source 1300.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

### Example #7: Power Sources with Integrated Electrodes

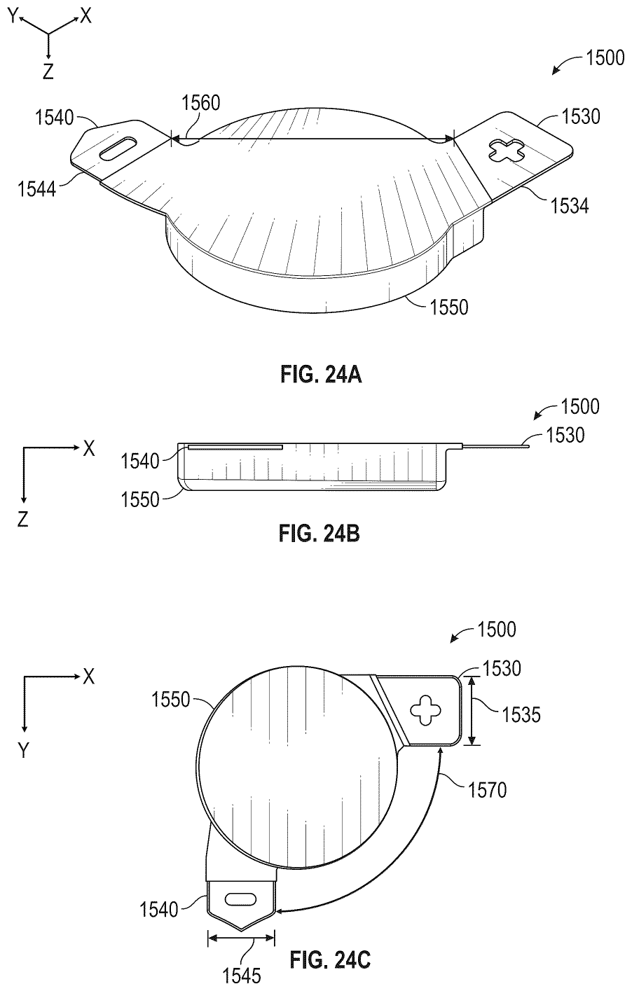

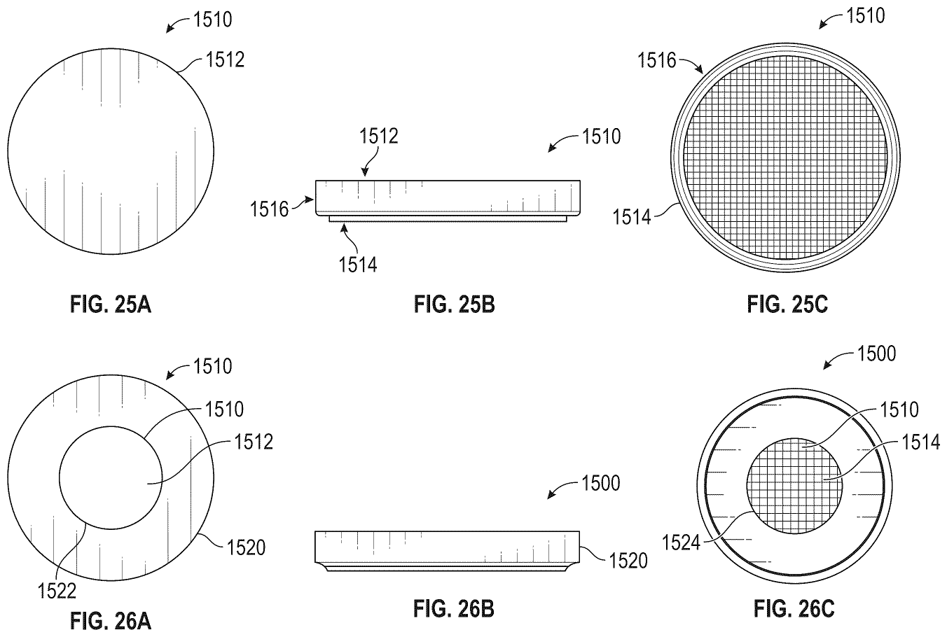

FIGS. 24A-24C illustrate a power source 1500, according to an example. The power source 1500 can include a battery 1510 (best shown in FIGS. 25A-25C), a first dielectric layer 1520 (best shown in FIGS. 26A-26C) covering at least a portion (for example, the entirety, or less then the entirety) of the battery 1510, a first electrode 1530 electrically coupled to a first terminal of the battery 1510, a second electrode 1540 coupled to a second terminal of the battery 1510, and a second dielectric layer 1550 at least partially wrapped around each of the battery 1510, the first electrode 1530, and the second electrode 1540. As shown, the power source 1500 can further include labels (for example, warning or safety labels) printed on the second dielectric layer 1550.

In some examples, the first dielectric layer 1520 and/or the second dielectric layer 1550 can further insulate the battery 1510 to further reduce the likelihood of a short circuit, while the uncovered portions of the electrodes 1530, 1540 not covered by the first dielectric layer 1520 and/or the second dielectric layer 1550 nonetheless allow the power source 1500 to be connected to a circuit, e.g., a flexible circuit. In some cases, the disclosed battery design eliminates the need for a separate battery holder.

In some examples, the exposed bottom surfaces (i.e., the surfaces facing in the negative Z-direction as shown in FIGS. 24A-24C) of the electrodes 1530, 1540 can be approximately coplanar. As used herein, the electrodes 1530, 1540 are “approximately coplanar” if no portion a surface of the first electrode 1530, e.g., a bottom surface of the first electrode 1530 facing the negative Z-direction, and no portion of a surface of the second electrode 1540, e.g., a bottom surface of the first electrode 1530 facing the negative Z-direction are spaced apart by more than ±1 millimeter, e.g., more than ±0.75 millimeters and/or more than ±0.5 millimeters in the Z-direction defined by the coordinate axes of FIGS. 24A-24B. In some examples, configuring the electrodes 1530, 1540 to be approximately coplanar can make it easier to connect the power source 1500 to a flexible circuit with corresponding coplanar circuit traces. Furthermore, since the electrode 1530, 1540 are integrated into the power source 1500, the power source can be connected to the flexible circuit without the use of a separate battery holder.

In some examples, the first dielectric layer 1520 and/or the second dielectric layer 1550 can help “child-proof” the power source 1500. For example, the first dielectric layer 1520 and second dielectric layer 1550 can together cover the entire outer surface of the battery 1510. Thus, if the power source 1500 is accidently swallowed by a child, no portion, or at least a reduced portion, of the covered battery will come into direct contact with saliva or other moisture that can trigger an electrical current and cause burns to the child's esophagus. In some examples, the first dielectric layer 1520 and/or the second dielectric layer 1550 can include a bittering agent (for example, a bitter coating) that discourages children from putting the power source 1500 in their mouths, thereby further reducing the likelihood that children will accidently swallow the power source 1500.

In some examples, the dielectric layer(s) 1520, 1550 can help contain any chemical leakage if the battery 1510 begins to leak. For example, if the battery 1510 begins to leak, all leakage will be contained within the first dielectric layer 1520 and/or the second dielectric layer 1550, thereby further reducing the likelihood that a child will accidently ingest potentially hazardous chemical leakage.

In some examples, it can be easier to print or affix a safety label to the dielectric layer (for example, the second dielectric layer 1550) than to a surface of the battery 1510, thereby making it easier to label to the power source 1500 with a safety warning.

FIGS. 25A-25C illustrate the battery 1510 of the power source 1500. As shown, the battery 1510 is a coin cell battery (for example, a CR2032 battery), which is also referred to herein as a “button cell battery.” However, the battery 1510 can be of any shape, size, or type, such as a AA battery, a AAA battery, or a 9V battery. The battery 1510 can have any power capacity or output voltage. For example, the battery 1510 can have an output voltage of approximately 3 volts (+10%).

As shown, the battery 1510 includes a first terminal 1512 (FIG. 25A), a second terminal 1514 (FIG. 25C) disposed on an opposite side of the battery than the first terminal 1512, and a side surface 1516 (FIG. 25B) disposed between and separating the first terminal 1512 and the second terminal 1514. In some examples, the first terminal 1512 can be a positive terminal and the second terminal 1514 can be a negative terminal. However, in other examples, the battery 1510 can include a single terminal having different portions with different polarities or a plurality of terminals having the same polarity. In some of these examples, having multiple terminals can with the same polarities can be useful if the battery 1510 is used to power multiple circuit elements, for example, circuit elements that can be attached to a flexible circuit in multiple orientations. In some examples, the side surface 1516 can be a circumferential surface. In some examples, the side surface 1516 can form a perimeter surface of the battery 1510.

Although the illustrated coin cell battery 1510 includes a circular first terminal 1512 and a circular second terminal 1514, other examples of the terminals 1512, 1514 can have different shapes or sizes (for example, square or rectangular terminals).

FIGS. 26A-26C illustrate the power source 1500, with the electrodes 1530, 1540 and the second dielectric layer 1550 removed to better illustrate the first dielectric layer 1520 at least partially wrapped around the battery 1510. As shown, when wrapped at around the battery 1510, the first dielectric layer 1520 defines a first aperture 1522 that leaves a central portion of the first terminal 1512 (FIG. 26A) uncovered by the first dielectric layer 1520 and additionally defines a second aperture 1524 (FIG. 26B) that leaves a central portion of the second terminal 1514 uncovered by the first dielectric layer 1520. Thus, the first dielectric layer 1520 can be configured to cover peripheral portions of the first terminal 1512 and the second terminal 1514 and cover the side surface 1516, while leaving central portions of the first terminal 1512 and the second terminal 1514 uncovered. In this way, the first dielectric layer 1520 can cover a portion of the battery 1510 to reduce the likelihood of electrical shorts and to better contain battery leakage, while still allowing for electrical contact between the first terminal 1512 and the first electrode 1530 and for electrical contact between the second terminal 1514 and the second electrode 1540.

In some examples, the first dielectric layer 1520 can instead define a single aperture that exposes at least portions of the first terminal 1512 and the second terminal 1514 that come into contact with the first electrode 1530 and the second electrode 1540, respectively.

The first dielectric layer 1520 can be a polymer dielectric layer, for example, a plastic dielectric layer. In some examples, the first dielectric layer 1520 can have a thickness in a range from approximately 0.1 millimeters to approximately 0.2 millimeters, such as approximately 0.12 millimeters (+10%), approximately 0.15 millimeters (+10%), or approximately 0.17 millimeters (+10%). In some examples, the first dielectric layer 1520 can be formed from a material capable of withstanding elevated temperatures for extended periods of time; for example, the first dielectric layer 1520 can be formed from a plastic material capable of withstanding a temperature of at least 70° Celsius for a period of at least 7 hours. Examples of such plastic materials can include, but are not limited to, polyvinyl chloride (PVC), polypropylene (PP), polyethylene (PE), or polytetrafluoroethylene (PTFE). In some examples, the first dielectric layer 1520 (which can also be referred to as a “first waterproof dielectric layer,” a “first waterproof layer,” a “first water-resistant dielectric layer,” a “first water-resistant layer,” a “first film layer,” a “a first film,” a “first coating layer,” and/or a “first coating”) a can be formed from an electrically insulating dielectric material. In some examples, the material forming the first dielectric layer 1520 can be a waterproof or water-resistant material, which can help further reduce the likelihood of contact between the battery 1510 and saliva or other moisture. It should be understood that the first dielectric layer 1520 can be formed from any suitable electrically insulating, waterproof, and/or water-resistant material. The first dielectric layer 1520 can be implemented as a film, a coating, or in any other suitable configuration.

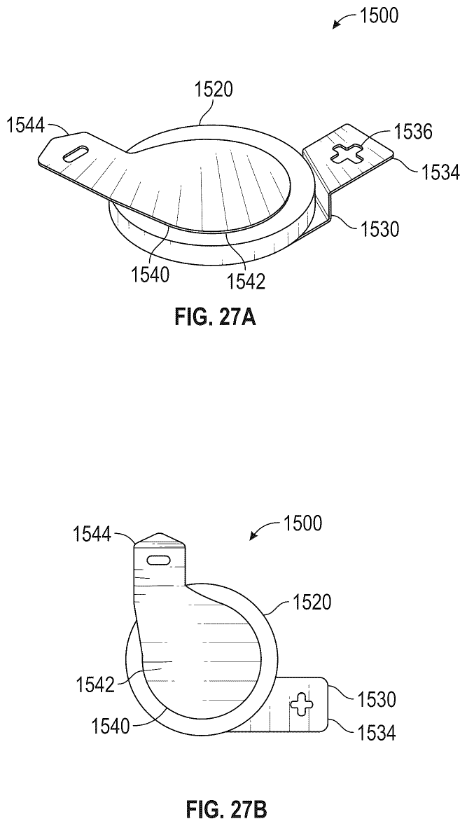

FIGS. 27A-27B illustrate the power source 1500, with the second dielectric layer 1550 removed to better illustrate the arrangement of the first dielectric layer 1520, the first electrode 1530, and the second electrode 1540. The first electrode 1530 can be configured to electrically couple the first terminal 1512 of the battery 1510 to a circuit trace (for example, circuit trace 340) of a flexible circuit while the battery 1510 is covered by the dielectric layers 1520, 1550. Similarly, the second electrode 1530 can be configured to electrically couple the second terminal 1514 of the battery 1510 to another circuit trace of the flexible circuit while the battery 1510 is covered by the dielectric layers 1520, 1550.

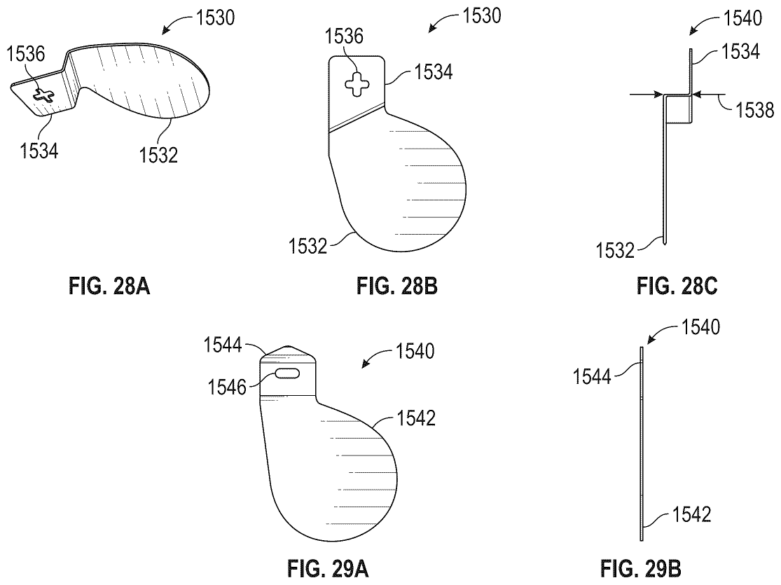

As shown in FIGS. 28A-28C, the first electrode 1530 can include a first end portion 1532 and a second end portion 1534. The first end portion 1532 is also referred to herein as a “proximal end portion” because it is closer to a central portion of the power source 1500 (for example, because it is closer to the battery 1510) than the second end portion 1534. The second end portion 1534 is also referred to herein as a “distal end portion” because it is further away from the central portion of the power source 1500 than the first end portion 1532. The first end portion 1532 can contact the first terminal 1512 of the battery 1510 through the first aperture 1522. The first end portion 1532 can define a circular profile having a greater diameter than a diameter of the first aperture 1522. In this way, the first end portion 1532 can completely cover the first aperture 1522, and thus the central portion of the first terminal 1512 exposed by the first aperture 1522, when the first end portion 1532 is placed over the first aperture 1522. Thus, the first end portion 1532 is not covered by the first dielectric layer 1520 when the power source 1500 is fully assembled.

In some examples, the first end portion 1532 can have a surface, and at least a portion of the surface can be configured to physically contact the first terminal 1512. In some examples, the area of the surface of the first end portion 1532 can be less than the area defined by the first terminal 1512, such that the first end portion 1532 covers less than the entirety of the first terminal 1512. In some examples, the area of the surface of the first end portion 1532 can be greater than or equal to the area defined the first terminal 1512, such that the first end portion 1532 can cover the entirety of the first terminal 1512.

In some examples, the first end portion 1532 can define a non-circular profile. For example, if the battery 1510 has a first terminal 1512 with a non-circular profile, the first end portion 1532 can have a similar non-circular profile. In some examples, the first aperture 1522 can have a non-circular profile, and the first end portion 1532 can have a non-circular profile similar to the non-circular profile of the first aperture 1522.

In some examples, the first end portion 1532 can be secured to the first terminal 1512 using an adhesive (for example, a thermally conductive adhesive) or solder. In some examples, the first end portion 1532 can be secured to the first terminal 1512 using a friction/pressure fit from the second dielectric layer 1550. In some examples, the first end portion 1532 can be secured to the first terminal 1512 using mechanical spring that biases the first end portion 1532 towards the first terminal 1512, or a mechanical fastener that mechanically couples the first end portion 1532 to the first terminal 1512. In some examples, the first end portion 1532 can be secured to the first terminal 1512 using a friction fit.

In some examples, the first end portion 1532 can have a profile of any shape, so long as the first end portion 1532 covers the entirety of the first aperture 1522, thus leaving no portion of the first terminal 1512 uncovered by either the first dielectric layer 1520 and/or the first electrode 1530.

The second end portion 1534 of the first electrode 1530 can be configured to be placed in electrical contact with a circuit trace (for example, circuit trace 340) or another portion of a flexible circuit. Thus, the second end portion 1534 is not covered by either the first dielectric layer 1520 or the second dielectric layer 1550 when the power source 1500 is fully assembled.

Now referring back to FIGS. 27A-27B and FIGS. 28A-28B, the second end portion 1534 of the first electrode 1530 can optionally include a cutout 1536 indicative of the polarity of the first electrode 1530 and the first terminal 1512 connected to the first electrode 1530. In some examples, the cutout 1536 can help better distinguish the positive and negative terminals of the power source 1500. In some examples, the cutout 1536 can be configured for use as a stencil, which can allow a person constructing a circuit including the power source 1500 to trace the shape of the cutout 1536 onto a substrate of the circuit. Tracing the shape of the cutout 1536 onto the substrate of the circuit allows a person constructing the circuit to easily mark the orientation of the power source 1500 on the substrate, which facilitates the easy reattachment of the power source 1500 to the substrate in case the power source 1500 needs to be removed.

Now referring back to FIG. 24C, the second end portion 1534 of the first electrode 1530 defines a minimum width 1535 in the XY-plane defined by the coordinate axis, e.g., in the Y-direction shown in FIG. 24C. As used herein, the term “minimum width” refers to the shortest straight-line distance across a body of an electrode, e.g., the electrode 1530, measured in a direction that is perpendicular to or within #10° of perpendicular to the length of the electrode within a defined plane, e.g., the XY-plane. This measurement corresponds to the narrowest cross-sectional span of the electrode and is intended to exclude diagonal or edge-to-edge distances that do not reflect a true width measurement across the electrode body.

While the minimum width may be sufficient to characterize the geometry of electrodes having relatively uniform or regular shapes, it may not adequately represent electrodes having localized notches, tapers, or other surface variations. In such cases, a single point of narrowness may not reflect the overall geometry of the electrode or its functional constraints (e.g., fit within a housing or thermal dissipation characteristics).

Accordingly, as used herein, the term “minimum average width” refers to the smallest average straight-line width measured across the body of the electrode over any continuous span of a predetermined length (e.g., 1 mm), within a given plane (e.g., the XY-plane), and along a direction that is perpendicular or within #10° of perpendicular to the length of the electrode. The minimum average width accounts for localized variations in width while capturing the narrowest functionally meaningful portion of the electrode, and in some examples may be more suitable for characterizing electrodes with non-uniform profiles.

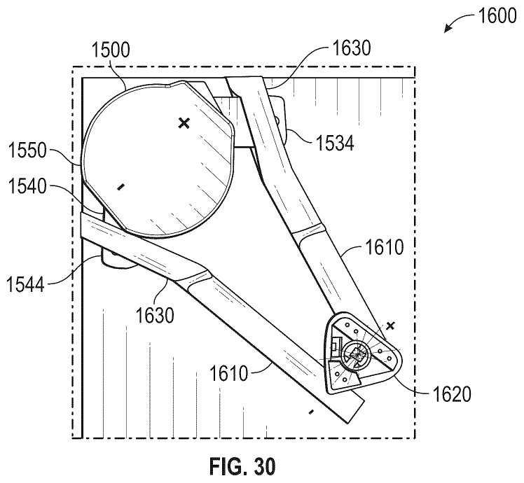

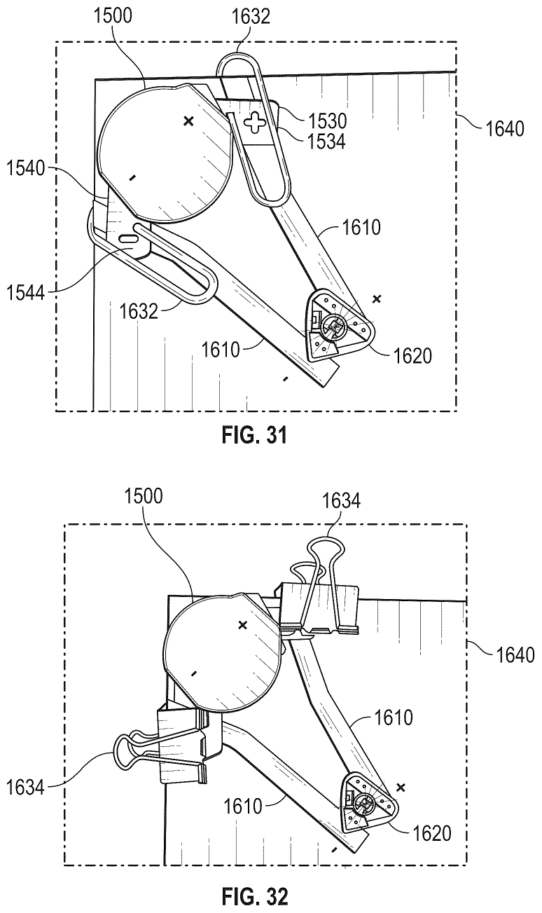

In some examples, the minimum average width of the first electrode 1530 can be at least 3 millimeters, at least 4 millimeters, at least 5 millimeters, at least 6 millimeters, and/or at least 7 millimeters. In such examples, the minimum average width can be selected such that the second end portion 1534 is compactly sized to allow for the easy and secure coupling of the second end portion 1534 of the first electrode 1530 to a substrate, e.g., the substrate 1640 (FIG. 30), while still providing the second end portion 1534 with sufficient surface area for attachment to a fastener, e.g., conductive tape 1630 (FIG. 30), a paper clip 1632 (FIG. 31), and/or a binder clip 1634 (FIG. 32).

In some examples, the first electrode 1530 and/or the second end portion 1534 of the first electrode 1530 can be configured to be “thin” to minimize the overall profile of the power source 1500. For example, an average minimum thickness in the Z-direction of the “thin” second end portion 1534 of the “thin” first electrode 1530 can be in a range from 0.05 millimeters to 0.70 millimeters, such as from 0.10 millimeters to 0.65 millimeters, 0.15 millimeters to 0.60 millimeters, 0.20 millimeters to 0.55 millimeters, and/or 0.25 millimeters to 0.50 millimeters. As used herein, the term “minimum thickness” refers to a shortest straight-line distance across a body of an electrode, e.g., the first electrode 1530, measured in a direction, e.g., the Z-direction for the first electrode 1530, that is perpendicular to or within #10° of perpendicular to both the width, e.g., in the Y-direction for the first electrode 1530, and the length, e.g., in the X-direction for the first electrode 1530, of the electrode within a defined plane, e.g., the YZ-plane. As used herein, the term “minimum average thickness” refers to a straight-line thickness measured across the body of the electrode over any continuous span of a predetermined length (e.g., 1 mm), within a given plane (e.g., the YZ-plane), and along a direction that is perpendicular or within +10° of perpendicular to both the width and the length of the electrode.

The first electrode 1530 can be formed from any sufficiently conductive material to conduct electrical power to the rest of the flexible circuit, including but not limited to spring steel, aluminum, copper, nickel, brass, or bronze.

As shown in FIGS. 29A-29B, the second electrode 1540 includes a first end portion 1542 and a second end portion 1544 opposite the first end portion 1542. The first end portion 1542 is also referred to herein as a “proximal end portion” because it is closer to a central portion of the power source 1500 (for example, because it is closer to the battery 1510) than the second end portion 1544. The second end portion 1544 is also referred to herein as a “distal end portion” because it is further away from the central portion of the power source 1500 than the first end portion 1542. The first end portion 1542 can contact the second terminal 1514 of the battery 1510 through the second aperture 1524. The first end portion 1542 can define a circular profile having a greater diameter than a diameter of the second aperture 1524. In this way, the first end portion 1542 can completely cover the second aperture 1524, and thus the central portion of the second terminal 1514 exposed by the second aperture 1524, when the first end portion 1542 of the second electrode 1540 is placed over the second aperture 1524. Thus, the first end portion 1542 is not covered by the first dielectric layer 1520 when the power source 1500 is fully assembled.

In some examples, the first end portion 1542 of the second electrode 1540 can have a surface, at least a portion of which is configured to physically contact the second terminal 1514. In some examples, the area of the surface of the first end portion 1542 can be less than the area defined the second terminal 1514, such that the first end portion 1542 covers less than the entirety of the second terminal 1514. In some examples the area of the surface of the second end portion 1542 can be greater than or equal to the area defined by the second terminal 1514, such that the first end portion 1542 can cover the entirety of the second terminal 1514.

In some examples, the first end portion 1542 of the second electrode 1540 can define a non-circular profile. For example, if the battery 1510 has a second terminal 1514 with a non-circular profile, the first end portion 1542 can have a similar non-circular profile. In some examples, the second aperture 1524 can have a non-circular shape, and the first end portion 1542 can have a non-circular profile similar to the non-circular shape of the second aperture 1524.

In some examples, the first end portion 1542 of the second electrode 1540 can have a profile of any shape, so long as the first end portion 1542 covers the entirety of the second aperture 1524, thus leaving no portion of the second terminal 1514 uncovered by either the first dielectric layer 1520 and/or the second electrode 1540.

The second end portion 1544 of the second electrode 1540 can be configured to be placed in electrical contact with a circuit trace (for example, circuit trace 340) of a flexible circuit. Thus, the second end portion 1544 is not covered by either the first dielectric layer 1520 or the second dielectric layer 1550 when the power source 1500 is fully assembled.

As shown in FIGS. 27A-27B and FIG. 29A, the second end portion 1544 can optionally include a cutout 1546 indicative of the polarity of the second electrode 1540 and the second terminal 1514 connected to the second electrode 1540. In some examples, the cutout 1546 can be configured for use as a stencil.

Now referring back to FIG. 24C, the second end portion 1544 of the second electrode 1540 defines a minimum width 1545 in the XY-plane defined by the coordinate axis, e.g., in the X-direction of FIG. 24C. In some examples, the minimum average width of the second electrode 1540, e.g., in the X-direction, can be at least 3 millimeters, at least 4 millimeters, at least 5 millimeters, at least 6 millimeters, and/or at least 7 millimeters. In such examples, the minimum average width can be selected such that the second end portion 1544 is compactly sized to facilitate the easy and secure coupling of the second end portion 1544 to a substrate, e.g., the substrate 1640 (FIG. 30), while still providing the second end portion 1544 with sufficient surface area for attachment to a fastener, e.g., conductive tape 1630 (FIG. 30), a paper clip 1632 (FIG. 31), or a binder clip 1634 (FIG. 32).

In some examples, the second electrode 1540 and/or the second end portion 1544 of the second electrode 1540 can be configured to be “thin” to minimize the overall profile of the power source 1500. For example, the thickness in the Z-direction (as defined by the coordinate axes of FIGS. 24A-24C) of the “thin” second end portion 1544 of the “thin” second electrode 1540 can be in a range from 0.05 millimeters to 0.70 millimeters, such as from 0.10 millimeters to 0.65 millimeters, 0.15 millimeters to 0.60 millimeters, 0.20 millimeters to 0.55 millimeters, and/or 0.25 millimeters to 0.50 millimeters.

In some examples, the second end portion 1534 of the first electrode 1530 and/or the second end portion 1540 of the second electrode 1540 can be shaped to contact a circuit trace (for example, circuit trace 340) or a circuit element of the flexible circuit. For example, the second end portion 1534 of the first electrode 1530 and/or the second end portion 1540 of the second electrode 1540 can include an indent or protrusion configured to mate with a corresponding protrusion or indent of the circuit trace or circuit element. In this way, the electrodes 1530, 1540 can be shaped to engage the circuit trace and/or circuit element in a certain configuration or orientation.

In some examples, the second end portion 1534 of the first electrode 1530 and the second end portion 1540 of the second electrode 1540 can have different profiles or shapes to further distinguish the first and second electrodes 1530, 1540. For example, the second end portion 1534 of the first electrode 1530 can have a squared-off shape and the second end portion 1544 of the second electrode 1540 can have a triangular or pointed shape. In this way, the different shapes of the first electrode 1530 and the second electrode 1540 can help a person assembling the flexible circuit further distinguish the different polarities of the electrodes 1530, 1540, i.e., to further distinguish the cathode and anode of the power source 1500.

Now referring back to FIGS. 27A, 28A, and 28C, the first end portion 1532 and the second end portion 1534 of the first electrode 1530 are offset from each other and are thus not coplanar. In other words, a first plane formed by the first end portion 1532 of the first electrode 1530 is not coplanar with a second plane formed by the second end portion 1534 of the first electrode 1530. For example, as best shown in FIG. 28C, the first end portion 1532 and the second end portion 1534 are not coplanar because they are offset from each other by an offset distance 1538. The offset distance 1538 can be equal to the thickness of the battery 1510 (in other words, the offset distance can be equal to the distance between the first terminal 1512 and the second terminal 1514 of the battery 1510). In some examples, such as the example shown in FIG. 27A, having the second end portion 1534 be offset from the first end portion 1532 can allow for the second end portion 1534 of the first electrode 1530 and the second end portion 1544 of the second electrode 1540 to be coplanar with each other when the power source 1500 is assembled. Having coplanar second end portions 1534, 1544 can make it easier to connect the electrodes 1530, 1540 of the power source 1500 to corresponding coplanar circuit traces (for example, circuit traces 340) of a flexible circuit.

The second electrode 1540 can be formed from any sufficiently conductive material to conduct electrical power to the rest of the flexible circuit, including but not limited to spring steel, aluminum, copper, nickel, brass, or bronze. In some examples, the first electrode 1530 and the second electrode 1540 can be formed from the same material. In some examples, the first electrode and the second electrode 1540 can be formed from different materials, which in some examples can have different conductivities. In some examples, forming the electrodes 1530, 1540 from different materials can help further distinguish the different electrodes 1530, 1540.

In some examples, the first end portion 1542 of the second electrode 1540 can be secured to the second terminal 1514 using an adhesive (for example, a thermally conductive adhesive) or solder. In some examples, the first end portion 1542 can be secured to the second terminal 1514 using a friction/pressure fit from the second dielectric layer 1550. In some examples, the first end portion 1542 can be secured to the second terminal 1514 using mechanical spring that biases the first end portion 1542 towards the second terminal 1514, or a mechanical fastener that mechanically couples the first end portion 1542 to the second terminal 1514. In some examples, the first end portion 1542 can be secured to the second terminal 1514 using a friction fit.

Reference is now made back to FIGS. 24A-24C, which illustrate the power source 1500 with the second dielectric layer 1550. As shown, the second dielectric layer 1550 is configured to be wrapped around at least a portion of the battery 1510, the first dielectric layer 1520, the first end portion 1532 of the first electrode 1530, and the first end portion 1542 of the second electrode 1540 such that only the second end portion 1534 of the first electrode 1530 and the second end portion 1544 of the second electrode 1544 are not covered by the second dielectric layer 1550. In some examples, leaving only the second end portions 1534, 1544 uncovered can help provide maximum insulation coverage for the battery 1510 and best mitigate any potential battery leakage.

The second dielectric layer 1550 (which can also be referred to as a “second waterproof dielectric layer,” a “second waterproof layer,” a “second water-resistant dielectric layer,” a “second water-resistant layer,” a “second film layer,” a “a second film,” a “second coating layer,” and/or a “second coating”) can be a polymer dielectric layer, for example, a plastic dielectric layer. In some examples, the second dielectric layer 1550 can have a thickness in a range from 0.1 millimeters to 0.2 millimeters, such as approximately 0.12 millimeters (+10%), approximately 0.15 millimeters (+10%), or approximately 0.17 millimeters (+10%). In some examples, the second dielectric layer 1550 can be formed from a material capable of withstanding elevated temperatures for extended periods of time; for example, the second dielectric layer 1550 can be formed from a plastic material capable of withstanding a temperature of at least 70° Celsius for a period of at least 7 hours. Examples of such plastic materials can include, but are not limited to, polyvinyl chloride (PVC), polypropylene (PP), polyethylene (PE), or polytetrafluoroethylene (PTFE). In some examples, the second dielectric layer 1550 can be formed from an electrically insulating dielectric material. In some examples, the material forming the second dielectric layer 1550 can be a waterproof or water-resistant material, which can help further reduce the likelihood of contact between the battery 1510 and saliva or other moisture. It should be understood that the second dielectric layer 1550 can be formed from any suitable electrically insulating, waterproof, and/or water-resistant material. The second dielectric layer 1550 can be implemented as a coating, a film, or any other suitable configuration. In some examples, the first and second dielectric layers 1520, 1550 can be formed from the same material or from different materials.

In some examples, the first dielectric layer 1520 and/or the second dielectric layer 1550 can include a substance (for example, a bitter coating) that tastes bitter, sour, salty, or otherwise unpleasant to dissuade children from putting the power source 1500 in their mouths. In such examples, such a substance can reduce the likelihood that a child will insert the power source 1500 into their mouth and then choke on the power source 1500.

The first electrode 1530 and the second electrode 1540 can be angularly offset from each other; in other words, the first electrode 1530 and the second electrode 1540 can be offset from each other about an axis extending through the first terminal 1512 and the second terminal 1514. For example, as best shown in FIG. 30C, the second end portion 1534 of the first electrode 1530 can extend in a first direction away from a central portion of the power source 1500 (in other words, away from the battery 1510), and the second end portion 1544 of the second electrode 1540 can extend in a second direction away from the central portion of the power source 1500.

As shown in FIG. 24A, the first and second electrodes 1530, 1540 can be spaced apart such that a minimum separation distance 1560 in the XY-plane (i.e., the plane defined by the second end portions 1534, 1544 of the first and second electrodes 1530, 1540) extends between the exposed and/or conductive second end portions 1534, 1544 of the first and second electrodes 1530, 1540. In some examples, the minimum separation distance 1560 can be at least 10 millimeters, at least 11 millimeters, at least 12 millimeters, at least 13 millimeters, at least 14 millimeters, at least 15 millimeters, at least 16 millimeters, at least 17 millimeters, at least 18 millimeters, at least 19 millimeters, at least 20 millimeters, etc. Furthermore, as shown in FIG. 24C, the first and second electrodes 1530, 1540 can be angularly offset from each other by an offset angle 1570. In some examples, the offset angle 1570 can be greater than or equal to approximately 75 degrees (+10%), greater than or equal to approximately 80 degrees (+10%), greater than or equal to approximately 85 degrees (+10%), and/or greater than or equal to approximately 90 degrees (+10%). In some examples, this spacing, offset, and/or combination thereof can help ensure adequate separation of the electrodes 1530, 1540 to prevent potential short circuits. However, the first electrode 1530 and the second electrode 1540 may have different spacings and/or offsets depending on the design of the flexible circuit and the position of the power source 1500 relative to the other components of the flexible circuit.

In some examples, the power source 1500 can be configured such that a current density at a dead short between surfaces (e.g., the lower surfaces) of the second end portions 1534, 1544 of the first and second electrodes 1530, 1540 is no greater than 25 mA/mm², and the average current density is no greater than 5 mA/mm² during momentary contact. As used herein, the term “momentary contact” refers to a brief interval during which current density is continuously evaluated-typically around 10 seconds in standardized testing. In some examples, momentary contact may correspond to a duration between approximately 5 and 15 seconds, or any interval sufficient to characterize short-duration contact risk. As used herein, “continuously evaluated” refers to sampling current density at a frequency sufficient to detect transient spikes during the interval, such as at least once per second, and preferably at a frequency consistent with the Nyquist criterion (i.e., at least twice the maximum expected frequency of current transients) to ensure accurate detection and characterization of short-duration current spikes.

In some examples, the power source 1500 can be assembled by first wrapping the battery 1510 in the first dielectric layer 1520, then placing the first end portion 1532 of the first electrode 1530 over the first aperture 1522 of the first dielectric layer 1520, then placing the first end portion 1542 of the second electrode 1540 over the second aperture 1524 of the first dielectric layer 1520, and then wrapping the battery 1510, the first dielectric layer 1520, the first end portion 1532 of the first electrode 1530, and the first end portion 1542 of the second electrode 1540 in the second dielectric layer 1550.

FIGS. 30-32 illustrate different methods of securing the power source 1500 to one or more circuit traces 1610 disposed on a substrate 1640 to form a closed circuit 1600 and provide electrical power to a circuit element 1620. The circuit element 1620 can be any one of the circuit elements described herein (for example, any one of circuit elements 380, 800, 900, 1000, 1200, 1400). As shown, the circuit traces 1610 electrically connect the first and second electrodes 1530, 1540 of the power source 1500 to the circuit element 1620, thereby forming a closed circuit with the circuit element 1620. In some examples, the substrate 1640 can be any one of the substrates described herein (for example, any one of substrates 120, 220, 320, 420, 520).

As shown in FIG. 30, the first and second electrodes 1530, 1540 can be secured to their respective circuit traces 1610 and/or the substrate 1640 using conductive tape 1630. In some examples, the conductive tape 1630 can share similarities with other conductive tapes described herein, such as the conductive tape 382.

As shown in FIG. 31, the first and second electrodes 1530, 1540 can alternatively be secured to their respective circuit traces 1610 and/or the substrate 1640 using paper clips 1632. As shown in FIG. 32, the first and second electrodes 1530, 1540 can alternatively be secured to their respective circuit traces 1610 and/or the substrate 1640 using binder clips 1634.

In some examples, the use of paper clips 1632 or binder clips 1634, which are easily manipulable by children, students, and hobbyists, can beneficially allow for easy assembly and/or disassembly of the flexible circuit 1600 without the use of tooling. In some examples, the paper clips 1632 or binder clips 1634 can be different colors to further distinguish the polarities of the electrodes 1530, 1540 connected thereto. It should be understood that the first and second electrodes 1530, 1540 can be secured to their corresponding circuit traces 1610 using any other suitable methods, including but not limited to adhesives, solder, mechanical fasteners, etc. In some examples, the first and second electrodes 1530, 1540 can simply be placed on top of their respective circuit traces 1610, such that electrical contact is established between the electrodes 1530, 1540 and the circuit traces 1610, without fixedly securing the power source 1500.

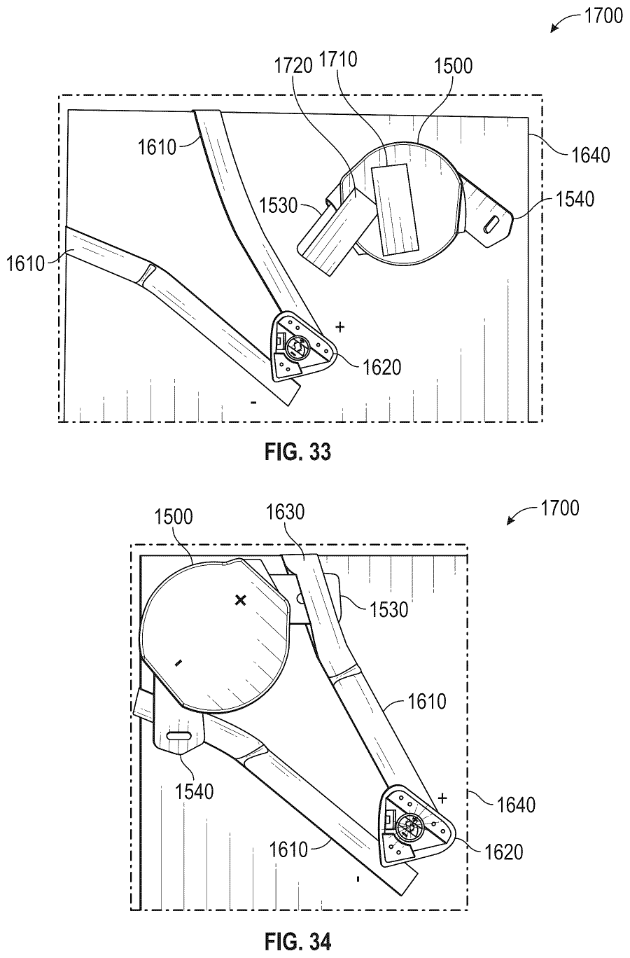

FIGS. 33-35 illustrate a flexible circuit 1700 that includes the power source 1500, one or more circuit traces 1610, and the circuit element 1620, the conductive tape 1630, and the substrate 1640, according to an example. The power source 1500, the circuit traces 1610, and the circuit element 1620 can each be coupled to the substrate 1640.

As shown in FIG. 33, a first foam piece 1710 can be adhered to a central portion of a bottom surface of the power source 1500. A second foam piece 1720 can be adhered to an electrode (for example, as shown, the first electrode 1530).

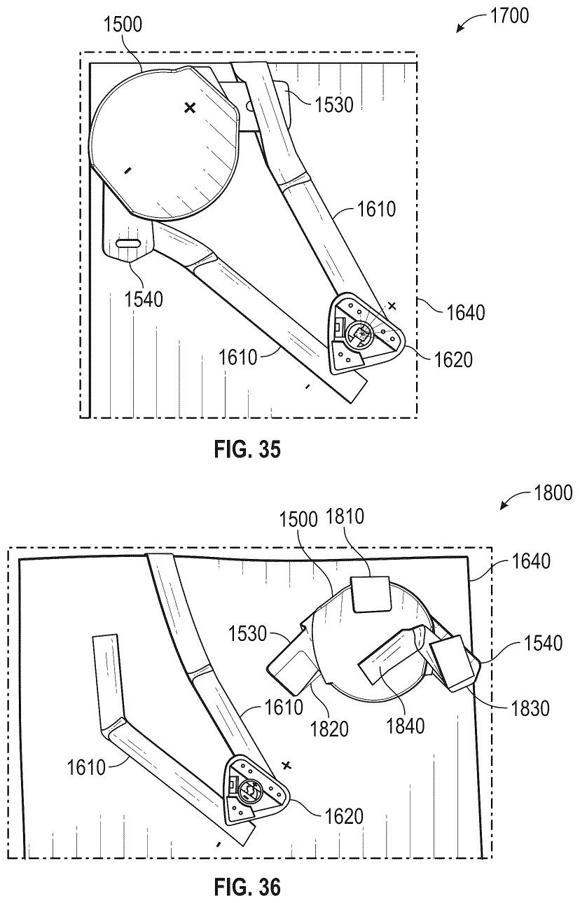

As shown in FIGS. 34-35, the power source 1500, with the first and second foam pieces 1710, 1720 attached thereto, can be placed on the substrate 1640. Then, the first electrode 1530 of the power source 1500 can be secured to one of the conductive traces 1610 using conductive tape 1630.

When the power source 1500 is placed on the substrate 1640 and connected to the conductive trace 1610, the first foam piece 1710 can act as a fulcrum about which the power source 1500 can pivot. For example, the power source 1500 can pivot from a first position in which the second electrode 1540 is cantilevered over—but not contacting—the other conductive trace 1610 (FIG. 34) to a second position in which the second electrode 1540 comes into electrical contact with the other conductive trace 1610 (FIG. 35), thereby completing the flexible circuit 1700. In this way, the power source 1500 and foam pieces 1710, 1720 can function together as a switch that allows electrical power to be selectively supplied to the circuit element 1620.

FIGS. 36-38 illustrate a flexible circuit 1800 that includes the power source 1500, one or more circuit traces 1610, and the circuit element 1620, the conductive tape 1630, and the substrate 1640, according to an example. The power source 1500, the circuit traces 1610, and the circuit element 1620 can each be coupled to the substrate 1640.

As shown in FIG. 36, a first foam piece 1810 can be coupled to a peripheral portion of the bottom surface of the power source 1500, a second foam piece 1820 can be coupled to the first electrode 1530 of the power source 1500, and a third foam piece 1830 can be coupled to the second electrode 1540 of the power source 1500. As further shown, a piece of conductive tape 1840 can be coupled to the second electrode 1540 and extend over at least a portion of the bottom surface of the power source 1500.

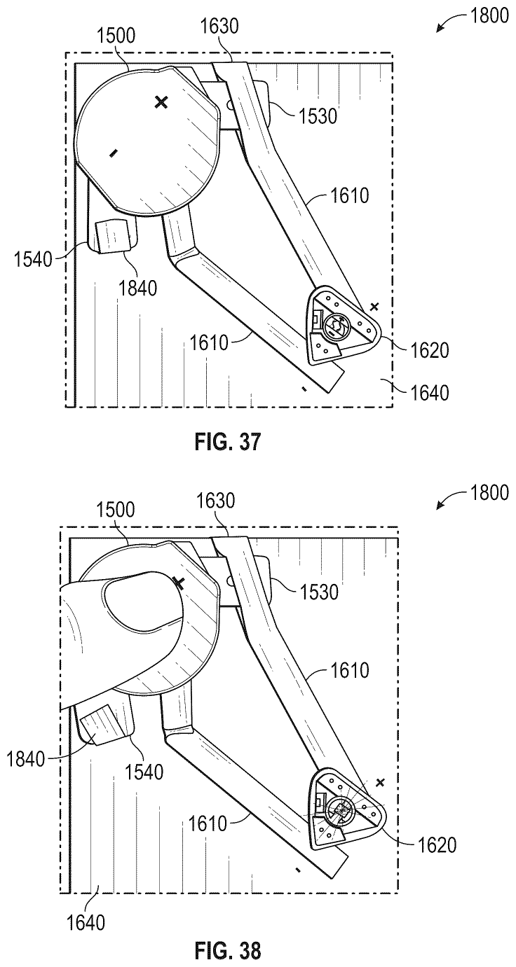

As shown in FIG. 37, the power source 1500—and the foam pieces 1810, 1820, 1830 and the piece of conductive tape 1840 coupled thereto—can be placed on the substrate 1640 such that the portion of the piece of conductive tape 1840 extending along the bottom surface of the power source 1500 is aligned with one of the conductive traces 1610. Thus, although the central portion of the power source 1500 is disposed over the conductive trace 1610, the second electrode 1540 is not disposed over the conductive trace 1610. The first electrode 1530 can be electrically coupled to the other conductive trace 1610.

As shown in FIG. 38, when the power source 1500 is pressed down (towards the substrate 1640), the foam pieces 1810, 1820, 1830 are compressed such that the piece of conductive tape 1840 comes into contact with the conductive trace 1610, thereby completing the circuit 1800. In this way, the power source 1500, the foam pieces 1810, 1820, 1830, and the piece of conductive tape 1840 can function together as a switch that allows electrical power to be selectively supplied to the circuit element 1620.

### Examples

In view of the above-described implementations of the disclosed subject matter, this application discloses the additional examples enumerated below. It should be noted that one feature of an example in isolation or more than one feature of the example taken in combination and, optionally, in combination with one or more features of one or more further examples are further examples also falling within the disclosure of this application.

Example 1. A flexible circuit kit can include at least one of a substrate and a toner ink layer printed onto the substrate or a circuit element. The flexible circuit kit can further include a carrier-backed foil that includes a metallized layer, a carrier layer coupled to the metallized layer, and an adhesive applied to the metallized layer. The adhesive can be selectively adherable to the toner ink layer.

Example 2. The flexible circuit kit of any example herein, particularly Example 1, wherein the carrier-backed foil can further include a release layer disposed between the metallized layer and the carrier layer, and wherein the carrier-backed foil does not include a lacquer layer disposed between the metallized layer and the release layer.

Example 3. The flexible circuit kit of any example herein, particularly any one of Examples 1-2, wherein the selectively adherable adhesive can be configured to not adhere to the substrate.

Example 4. The flexible circuit kit of any example herein, particularly any one of Examples 1-3, wherein the flexible circuit kit includes the substrate and the toner ink layer printed onto the substrate, and wherein the substrate can be at least a portion of a book.

Example 5. The flexible circuit kit of any example herein, particularly any one of Examples 1-3, wherein the flexible circuit kit includes the substrate and the toner ink layer printed onto the substrate, and wherein the substrate can be at least a portion of a bag.

Example 6. The flexible circuit kit of any example herein, particularly any one of Examples 1-3, wherein the flexible circuit kit includes the substrate and the toner ink layer printed onto the substrate, and wherein the substrate can be at least a portion of a box.

Example 7. The flexible circuit kit of any example herein, particularly any one of Examples 1-6, wherein the substrate can be formed from paper.

Example 8. The flexible circuit kit of any example herein, particularly any one of Examples 1-7, wherein the flexible circuit kit can include the circuit element, and wherein the circuit element can be a circuit sticker that includes a flexible polyimide substrate, a wiring element, and an anisotropic conductive tape film bonding the flexible polyimide substrate to the wiring element.

Example 9. A flexible circuit kit can include a carrier-backed foil and at least one of a substrate and a toner ink layer disposed at least partially over the substrate or a circuit element. The carrier-backed foil can include an adhesive layer, a metallized layer, a release layer directly coupled to the metallized layer, and a carrier layer. The adhesive layer of the carrier-backed foil can be selectively adherable to the toner ink layer.

Example 10. The flexible circuit kit of any example herein, particularly Example 9, wherein the adhesive layer of the carrier-backed foil can be configured to not adhere to the substrate.

Example 11. The flexible circuit kit of any example herein, particularly any one of Examples 9-10, wherein the substrate can include at least one of an embossed region or a debossed region.

Example 12. The flexible circuit kit of any example herein, particularly any one of Examples 9-11, wherein the circuit element can include an attachment clip, a first lead coupled to the attachment clip, and a second lead coupled to the attachment clip.

Example 13. The flexible circuit kit of any example herein, particularly any one of Examples 9-11, wherein the circuit element can include an attachment magnet, a first lead coupled to the attachment magnet, and a second lead coupled to the attachment magnet.

Example 14. The flexible circuit kit of any example herein, particularly any one of Examples 9-12, wherein the kit can further include a power source, wherein the power source can include one of an attachment clip or an attachment magnet.

Example 15. The flexible circuit kit of any example herein, particularly any one of Examples 9-14, wherein the substrate can be formed from paper.

Example 16. A method of assembling a flexible circuit can include: placing a carrier-backed foil over a substrate and a toner ink layer printed onto the substrate, pressing the carrier-backed foil against the substrate and the toner ink layer, heating the carrier-backed foil, the substrate, and the toner ink layer, and removing a portion of the carrier-backed foil to form a circuit trace. The carrier-backed foil can include an adhesive that is selectively adherable to the toner ink layer.

Example 17. The method of any example herein, particularly Example 16, wherein the method can further include, prior to placing the carrier-backed foil over the substrate and the toner ink layer: generating a flexible circuit trace pattern, and printing the flexible circuit trace pattern onto the substrate to form the toner ink layer.

Example 18. The method of any example herein, particularly Example 17, wherein the flexible circuit trace pattern can be printed using a laser printer.

Example 19. The method of any example herein, particularly any one of Examples 16-18, wherein the carrier-backed foil can include an adhesive layer, a metallized layer, a release layer directly coupled to the metallized layer, and a carrier layer, and wherein removing the portion of the carrier-backed foil can include separating the release layer and the carrier layer from the metallized layer.

Example 20. The method of any example herein, particularly any one of Examples 16-19, wherein the carrier-backed foil and the substrate can be heated using a laminator.

Example 21. The method of any example herein, particularly any one of Examples 16-20, wherein the method can further include, prior to pressing the carrier-backed foil against the substrate, placing a sheet over the carrier-backed foil, the substrate, and the toner ink layer.

Example 22. A method can include providing a flexible circuit kit that includes at least one of a toner ink layer printed over a paper substrate or a circuit element, and a carrier-backed foil comprising an adhesive configured to selectively adhere to the toner ink layer. The method can further include, with a server computing system, over a computing network, receiving a request to download a flexible circuit trace pattern, and with the server computing system, in response to receiving the request over the computing network, providing a computer-readable file comprising the flexible circuit trace pattern.

Example 23. The method of any example herein, particularly Example 22, wherein the flexible circuit kit can include a download code, and wherein the request can include the download code.

Example 24. The method of any example herein, particularly any one of Examples 22-23, wherein the substrate can include paper.

Example 25. A power source can include a battery with a first terminal and a second terminal, a first electrode coupled to the first terminal of the battery, a second electrode coupled to the second terminal of the battery, and a dielectric layer wrapped around the battery and partially wrapped around the first electrode and the second electrode.

Example 26. The power source of any example herein, particularly Example 25, wherein the first electrode can include a proximal end portion and a distal end portion opposite the proximal end portion, the second electrode can include a proximal end portion and a distal end portion opposite the proximal end portion, the proximal end portions of the first and second electrodes can be covered by the dielectric layer, and the distal end portions of the first and second electrodes are not covered by the dielectric layer.

Example 27. The power source of any example herein, particularly Example 26, wherein: the dielectric layer can be a second dielectric layer, the power source can further include a first dielectric layer wrapped around the battery, and the second dielectric layer can be wrapped around the first dielectric layer.

Example 28. The power source of any example herein, particularly Example 27, wherein the first dielectric layer can include at least one aperture, wherein the proximal end portion of the first electrode can contact the first terminal of the battery through the at least one aperture, and wherein the proximal end portion of the second electrode can contact the second terminal of the battery through the at least one aperture.

Example 29. The power source of any example herein, particularly Example 28, wherein the at least one aperture can include a first aperture aligned with the first terminal of the battery and a second aperture aligned with the second terminal of the battery.

Example 30. The power source of any example herein, particularly Example 29, wherein the proximal end portion of the first electrode can define a circular profile having a diameter greater than a diameter of the first aperture.

Example 31. The power source of any example herein, particularly any one of Examples 29-30, wherein the proximal end portion of the second electrode can define a circular profile having a diameter greater than a diameter of the second aperture.

Example 32. The power source of any example herein, particularly any one of Examples 26-31, wherein the proximal end portion and the distal end portion of the first electrode are not coplanar.

Example 33. The power source of any example herein, particularly Example 32, wherein the proximal end portion and the distal end portion of the first electrode can be offset from each other by a distance equal to a thickness of the battery.

Example 34. The power source of any example herein, particularly any one of Examples 26-33, wherein the proximal end portion and the distal end portion of the second electrode can be coplanar.

Example 35. The power source of any example herein, particularly any one of Examples 26-34, wherein at least one of the distal end portion of the first electrode and the distal end portion of the second electrode can include a cutout indicating the polarity of the respective electrode.

Example 36. A method of fabricating a power source can include coupling a first electrode to a battery, coupling a second electrode to the battery, and wrapping a dielectric layer around at least portions of the battery, the first electrode, and the second electrode.

Example 37. The method of any example herein, particularly Example 36, wherein the dielectric layer can be a second dielectric layer, and wherein the method can further include, prior to coupling the first electrode to the battery, wrapping the battery in a first dielectric layer.

Example 38. The method of any example herein, particularly Example 37, wherein coupling the first electrode to the battery can include aligning the first electrode with a first aperture in the first dielectric layer, and coupling the second electrode to the battery can include aligning the second electrode with a second aperture in the first dielectric layer.

Example 39. The method of any one of claim 36-38, wherein the battery can be a coin cell battery.

Example 40. A kit can include a power source, a first electrode, a second electrode, and a dielectric layer. The power source can include a battery with a first terminal and a second terminal. The first electrode can be coupled to the first terminal of the battery. The second electrode can be coupled to the second terminal of the battery. The dielectric layer can be wrapped around the battery and partially wrapped around the first electrode and the second electrode. The kit can further include at least one of a substrate and a circuit element, wherein the power source can be configured to be coupled to the substrate and the circuit element.

Example 41. The kit of any example herein, particularly Example 41, wherein the substrate can include a toner ink layer, and wherein the kit can further include a carrier-backed foil with a metallized layer, a carrier layer coupled to the metallized layer, and an adhesive applied to the metallized layer. The adhesive can be configured to be selectively adherable to the toner ink layer of the substrate.

Example 42. The kit of any one of claims 40-41, which can further include a foam piece configured to be coupled to the power source, wherein the foam piece is configured to act as a fulcrum about which the power source can pivot from a first position to a second position when the power source and the foam piece are coupled to the substrate.

Example 43. The kit of any example herein, particularly Example 42, wherein the power source can be configured to supply electrical power to the circuit element in the second position but not in the first position.

Example 44. The kit of example herein, particularly any one of Examples 40-43, wherein the power source can be configured to be coupled to the substrate and the circuit element without the use of a separate battery holder.

Example 45. A power source can include a battery with a first terminal and a second terminal, a first electrode coupled to the first terminal of the battery, and a second electrode coupled to the second terminal of the battery.

Example 46. The power source of any example herein, particularly Example 45, wherein the battery can be a coin cell battery having a first terminal on a first side of the battery and a second terminal on a second side of the battery.

Example 47. The power source of any example herein, particularly Example 46, wherein the first electrode can include a proximal end portion coupled to the first terminal of the battery and a distal end portion opposite the proximal end portion, the second electrode can include a proximal end portion coupled to the second terminal of the battery and a distal end portion opposite the proximal end portion, and the distal end portions of the first and second electrodes can be coplanar.

Example 48. A power source can include a battery with a first surface a second surface, a first terminal disposed on the first surface of the battery, and a second terminal disposed on the second surface of the battery. The first surface of the battery and the second surface of the battery can be separated by a third surface disposed between the first surface of the battery and the second surface of the battery, the third surface can be a side surface extending between the first and second surfaces and forming a perimeter surface of the battery, and the second surface can be opposite the first surface. The first terminal can have a first polarity, the second terminal can have a second polarity, and the second polarity can be different than the first polarity. The power source can further include a first electrode with a first end portion electrically coupled to the first terminal of the battery and a second end portion opposite the first end portion of the first electrode. The second end portion of the first electrode does not physically contact the first terminal of the battery. The power source can further include a second electrode with a first end portion electrically coupled to the second terminal of the battery and a second end portion opposite the first end portion of the second electrode. The second end portion of the second electrode does not physically contact the second terminal of the battery, and the second end portion of the first electrode and the second end portion of the second electrode are not in physical contact each other. The power source can further include a dielectric layer wrapped around at least a portion of the battery, the first end portion of the first electrode, and the first end portion of the second electrode. The dielectric layer does not cover the second end portion of the first electrode, and the dielectric layer does not cover the second end portion of the second electrode.

Example 49. The power source of any example herein, particularly Example 48, wherein a current density at a dead short between a surface of the second end portion of the first electrode and a surface of the second end portion of the second electrode can be no greater than 25 mA/mm² during momentary contact and can be no greater than an average of 5 mA/mm² during the momentary contact.

Example 50. The power source of any example herein, particularly Example 48, wherein the second end portion of the first electrode and the second end portion of the second electrode can be angularly offset from each other about an axis extending through the first terminal of the battery and the second terminal of the battery such that the second end portion of the first electrode can extend away from a central portion of the battery in a first direction and the second end portion of the second electrode extends away from the central portion of the battery in a second direction, wherein the first direction can be different than the second direction, and wherein the second end portion of the first electrode and the second end portion of the second electrode can be angularly offset from each other by an angle of at least 75 degrees.

Example 51. The power source of any example herein, particularly Example 48, wherein the second end portion of the first electrode and the second end portion of the second electrode can be approximately coplanar.

Example 52. The power source of any example herein, particularly Example 51, wherein the second end portion of the first electrode and the second end portion of the second electrode can define a minimum separation distance therebetween, and wherein the minimum separation distance can be greater than or equal to 15 millimeters.

Example 53. The power source of any example herein, particularly Example 51, wherein the second end portion of the first electrode can have a minimum average width, the minimum average width of the second end portion of the first electrode can be greater than or equal to 6 millimeters, the second end portion of the second electrode can have a minimum average width, and the minimum average width of the second end portion of the second electrode can be greater than or equal to 6 millimeters.

Example 54. The power source of any example herein, particularly Example 48, wherein the second end portion of the first electrode and the second end portion of the second electrode can be approximately coplanar with the second surface of the battery.

Example 55. The power source of any example herein, particularly Example 48, wherein the first end portion of the first electrode and the second end portion of the first electrode can be offset from each other by a distance equal to a thickness of the battery, and wherein the thickness of the battery is a distance between the first terminal of the battery and the second terminal of the battery.

Example 56. The power source of any example herein, particularly Example 48, wherein the first end portion of the second electrode and the second end portion of the second electrode can be approximately coplanar.

Example 57. A method of fabricating a power source can include: coupling a proximal end portion of a first electrode to a first terminal of a battery. The battery can include a first surface and a second surface. The first surface of the battery and the second surface of the battery can be separated by a third surface disposed between the first surface of the battery and the second surface of the battery, the third surface can be a side surface, and the second surface can be opposite the first surface. The battery can further include the first terminal disposed on the first surface of the battery, wherein the first terminal can have a first polarity, and a second terminal disposed on the second surface of the battery, wherein the second terminal can have a second polarity, and wherein the second polarity can be different than the first polarity. The first electrode can include the proximal end portion and a distal end portion opposite the proximal end portion of the first electrode, wherein the distal end portion of the first electrode does not physically contact the first terminal of the battery. The method can further include coupling a proximal end portion of a second electrode to the second terminal of the battery, wherein the second electrode can include the proximal end portion and a distal end portion opposite the proximal end portion of the second electrode, wherein the distal end portion of the second electrode does not physically contact the second terminal of the battery, and wherein the distal end portion of the first electrode and the distal end portion of the second electrode do not physically contact each other. The method can further include wrapping a dielectric layer around at least a portion of the battery, the proximal end portion of the first electrode, and the proximal end portion of the second electrode. Wrapping the dielectric layer does not include wrapping the dielectric layer around the distal end portion of the first electrode, and wrapping the dielectric layer does not include wrapping the dielectric layer around the distal end portion of the second electrode.

Example 58. The method of any example herein, particularly Example 57, wherein the dielectric layer can be a second dielectric layer, and wherein the method can further include, prior to coupling the proximal end portion of the first electrode to the first terminal of the battery, wrapping at least a portion of the battery in a first dielectric layer.

Example 59. The method of any example herein, particularly Example 58, wherein the first dielectric layer can include a first aperture and a second aperture, coupling the proximal end portion of the first electrode to the first terminal of the battery can include aligning the proximal end portion of the first electrode with the first aperture of the first dielectric layer, and coupling the proximal end portion of the second electrode to the second terminal of the battery can include aligning the proximal end portion of the second electrode with the second aperture of the first dielectric layer.

Example 60. The method of any example herein, particularly Example 59, wherein the proximal end portion of the first electrode can have a surface defining an area, at least a portion of the surface of the first electrode can be configured to physically contact the first terminal of the battery, and the area of the surface of the first portion of the electrode can be greater than or equal to an area defined by the first terminal of the battery.

Example 61. The method of any example herein, particularly Example 59, wherein the proximal end portion of the second electrode can have a surface defining an area, at least a portion of the surface of the second electrode can be configured to physically contact the second terminal of the battery, and the area of the surface of the second portion of the electrode can be greater than or equal to an area defined by the second terminal of the battery.

Example 62. The method of any example herein, particularly Example 57, wherein the dielectric layer can include a waterproof or water-resistant material.

Example 63. A kit can include a power source and at least one of a substrate and a circuit element, wherein the power source can be configured to be coupled to the substrate or the circuit element. The power source can include a battery with a first surface, a second surface opposite the first surface, wherein the first surface of the battery and the second surface of the battery can be separated by a third surface disposed between the first surface of the battery and the second surface of the battery, a first terminal having a first polarity, wherein the first terminal can be located on the first surface of the battery, and a second terminal having a second polarity different than the first polarity of the first terminal, wherein the second terminal can be disposed on the second surface of the battery. The power source can further include a first electrode with a first end portion in contact with the first terminal of the battery and a second end portion not in physical contact the first terminal of the battery, a second electrode with a first end portion in contact with the second terminal of the battery and a second end portion not in physical contact the second terminal of the battery, wherein the second end portion of the first electrode and the second end portion of the second electrode do not physically contact each other, and a dielectric coating disposed around at least a portion of the battery including the first and second terminals of the battery, wherein the dielectric coating can cover the first end portion of the first electrode, wherein the dielectric coating can cover the first end portion of the second electrode, wherein the dielectric coating does not cover the second end portion of the first electrode, and wherein the dielectric coating does not cover the second end portion of the second electrode.

Example 64. The kit of any example herein, particularly Example 63, wherein the kit can further include a conductive tape, and wherein at least one of the second end portion of the first electrode and the second end portion of the second electrode can be configured to be coupled to the conductive tape.

Example 65. The kit of any example herein, particularly Example 63, wherein at least one of the second end portion of the first electrode and the second end portion of the second electrode can include a cutout configured for use as a stencil.

Example 66. The kit of any example herein, particularly Example 63, wherein the second end portion of the first electrode can have a first shape configured to indicate a polarity of the first electrode, wherein the second end portion of the second electrode can have a second shape configured to indicate a polarity of the second electrode, and wherein the first shape can be different than the second shape.

Example 67. The kit of any example herein, particularly Example 63, wherein the substrate can include a toner ink layer, and wherein the kit can further include a carrier-backed foil with a metallized layer, a carrier layer coupled to the metallized layer, and an adhesive applied to the metallized layer, wherein the adhesive can be configured to be selectively adherable to the toner ink layer of the substrate.

Example 68. The power source of any example herein, wherein at least one of the first electrode and the second electrode is a thin electrode configured to minimize an overall profile of the power source.

The features described herein with regard to any example can be combined with other features described in any one or more of the other examples, unless otherwise stated. For example, any one or more of the features of one flexible circuit kit can be combined with any one or more features of another flexible circuit kit. As another example, any one or more of the features of one power source can be combined with any one or more features of another power source. As another example, any one or more features of one method can be combined with any one or more features of another method.

In view of the many possible ways in which the principles of the disclosure may be applied, it should be recognized that the illustrated configurations depict examples of the disclosed technology and should not be taken as limiting the scope of the disclosure nor the claims. Rather, the scope of the claimed subject matter is defined by the following claims and their equivalents.

We claim:

1. A flexible circuit comprising:
a substrate comprising a first surface and a second surface, wherein the substrate is formed from an electrically non-conductive material;
a plurality of polymer particles deposited onto a first region of the first surface of the substrate according to a circuit trace pattern, wherein the circuit trace pattern defines a path on the first region of the first surface of the substrate of at least one conductive circuit trace configured to couple electrically to a circuit element, wherein the plurality of polymer particles are not disposed on a second region of the first surface of the substrate, and wherein the first region of the first surface of the substrate is adjacent the second region of the first surface of the substrate; and
an electrically conductive metallized foil comprising a metallized layer formed from an electrically conductive material, wherein the electrically conductive metallized foil is configured to adhere to the polymer particles deposited onto the first region of the first surface of the substrate but not adhere to the second region of the first surface of the substrate on which the polymer particles are not deposited to form the at least one conductive circuit trace on the first region of the first surface of the substrate, and wherein the metallized layer is disposed above the polymer particles and the first surface of the substrate.

2. The flexible circuit of claim 1, wherein the electrically non-conductive material of the substrate comprises at least one of paper, cardboard, cloth, plastic, or a rigid material.

3. The flexible circuit of claim 1, wherein the electrically conductive material of the metallized layer of the metallized foil comprises at least one of aluminum, copper, gold, or silver.

4. The flexible circuit of claim 1, wherein the first region of the first surface of the substrate is an embossed region of the first surface of the substrate or debossed region of the first surface of the substrate.

5. The flexible circuit of claim 1, further comprising at least one circuit element configured to couple electrically to the conductive circuit trace.

6. The flexible circuit of claim 1, further comprising a power source configured to couple to the conductive circuit trace via an attachment magnet, an attachment clip, or an adhesive.

7. A method of forming a circuit comprising:
depositing a plurality of polymer particles onto a first region of a first surface of a substrate according to a circuit trace pattern, wherein the substrate comprises the first surface and a second surface, wherein the substrate is formed from an electrically non-conductive material, wherein the circuit trace pattern defines a path of a conductive circuit trace configured to couple electrically to a circuit element, and wherein the polymer particles are not deposited onto a second region of the first surface of the substrate;
placing a metallized foil over the polymer particles and the first region of the first surface of the substrate, wherein the metallized foil comprises a metallized layer formed from an electrically conductive material;
applying heat to the metallized foil and the polymer particles to selectively adhere the metallized foil to the polymer particles deposited onto the first region of the first surface of the substrate but not to the second region of the first surface of the substrate; and
removing a non-adhered portion of the metallized foil to form a conductive circuit trace on the first region of the first surface of the substrate.

8. The method of claim 7, wherein the polymer particles are deposited via a laser printer.

9. The method of claim 7, wherein the heat is applied via a laminator.

10. The method of claim 7, wherein applying heat to the metallized foil and the polymer particles further comprises applying pressure to the metallized foil.

11. The method of claim 7, wherein the metallized foil comprises a metallized layer and a selectively-adherable adhesive coupled to the metallized layer, wherein the adhesive is configured to bond to the polymer particles but not to the substrate.

12. The method of claim 11, wherein the selectively-adherable adhesive forms an adhesive layer underneath the metallized layer.

13. The method of claim 7, further comprising, prior to depositing the polymer particles onto the first region of the first surface of the substrate:
receiving a computer-readable file comprising a circuit trace pattern from a server,
wherein depositing the polymer particles onto the first region of the first surface of the substrate according to the circuit trace pattern comprises depositing the polymer particles in the shape of the circuit trace pattern onto the first region of the first surface of the substrate.

14. The method of claim 13, wherein the computer-readable file is a binary image file, a grayscale image file, or a multicolor image file.

15. The method of claim 7, further comprising, prior to depositing the polymer particles onto the first region of the first surface of the substrate, generating the circuit trace pattern.

16. A foil-based circuit kit comprising:
a carrier-backed foil comprising at least a metallized layer and a carrier layer coupled to the metallized layer, wherein the carrier-backed foil is configured to adhere to a plurality of polymer particles deposited onto a first region of a first surface of a substrate but not adhere to a second region of the first surface of the substrate on which polymer particles are not deposited, wherein the substrate is formed from an electrically non-conductive material, and wherein the metallized layer is formed from an electrically conductive material; and
a circuit element, wherein the circuit element is configured to be coupled to the metallized layer of the carrier-backed foil to form at least a portion of an electric circuit.

17. The foil-based circuit kit of claim 16, wherein the circuit element comprises an LED, a sensor, or a microcontroller.

18. The foil-based circuit kit of claim 16, wherein the foil-based circuit kit comprises a substrate and a plurality of polymer particles pre-deposited on the substrate in the shape of a circuit trace pattern, and wherein the circuit trace pattern defines a path of a conductive circuit trace configured to couple electrically to the circuit element to form the at least portion of the electric circuit.

19. The foil-based circuit kit of claim 16, wherein the carrier-backed foil comprises an adhesive coupled to the metallized layer, and wherein the adhesive layer is selectively adherable to the polymer particles but not to the substrate.

20. The foil-based circuit kit of claim 16, wherein the carrier-backed foil further comprises a release layer disposed between the metallized layer and the carrier layer, and wherein the carrier-backed foil does not include a lacquer layer disposed between the metallized layer and the release layer.
